(19) United States
(12) Patent Application Publication
(10) Pub. No.: US 2010/0314671 A1
(43) Pub. Date: Dec. 16, 2010

(54) Semiconductor device and method of forming the same

(75) Inventors: Kiyonori Oyu, Tokyo (JP); Kazuhiro Nojima, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/801,459

(22) Filed: Jun. 9, 2010

(30) Foreign Application Priority Data
Jun. 11, 2009 (JP) P2009-140493

(51) Int. Cl. H01L 29/78; H01L 29/02

(52) U.S. Cl. 257/255; 257/288; 257/E29.002; 257/E29.255

(57) ABSTRACT

A semiconductor device includes a semiconductor substrate, and an extending semiconductor portion that extends vertically from the semiconductor substrate. The extending semiconductor portion has a side surface which comprises four main surfaces of {100} face and four sub-surfaces of {110} face. The four sub-surfaces are smaller in area than the four main surfaces.

### BACKGROUND OF THE INVENTION

1. Field of the Invention

The present invention relates to a semiconductor device and a method of manufacturing the semiconductor device.

Priority is claimed on Japanese Patent Application No. 2009-140493, filed Jun. 11, 2009, the content of which is incorporated herein by reference.

2. Description of the Related Art

Pillar MOS transistors of the related art have been known. The pillar MOS transistor includes semiconductor pillars. The pillars are shaped in circle or rectangle in plan view.

Japanese Unexamined Patent Application Publication No. 2007-250652 in FIG. 1 discloses a pillar MOS transistor including a pillar which is shaped in circle in plan view.

Japanese Unexamined Patent Application Publication No. 2008-140996 in FIG. 1 discloses a pillar MOS transistor including a pillar which is shaped in rectangle in plan view.

Japanese Unexamined Patent Application Publication No. 2003-007790 discloses a method of evaluating plan-direction dependence of a semiconductor substrate. Japanese Unexamined Patent Application Publication No. 2003-007790 further discloses that a polygonal silicon pillar with (110)-face is used for evaluation on plan-direction. The polygonal silicon pillar is shaped in rectangle in plan view.

### SUMMARY

In one embodiment, a semiconductor device may include, but is not limited to, a semiconductor substrate, and an extending semiconductor portion that extends vertically from the semiconductor substrate. The extending semiconductor portion has a side surface which comprises four main surfaces of {100} face and four sub-surfaces of {110} face. The four sub-surfaces are smaller in area than the four main surfaces.

In another embodiment, a semiconductor device may include, but is not limited to, a semiconductor substrate, an extending semiconductor portion, a gate insulating film and a first gate electrode. The extending semiconductor portion extends vertically from the semiconductor substrate. The extending semiconductor portion have a side surface which comprises four main surfaces of {100} face and four sub-surfaces of {110} face. A total area of the four sub-surfaces is smaller than a total area of the four main surfaces. A gate insulating film includes four main portions covering the four main surfaces of {100} face, and four sub-portions covering the four sub-surfaces of {110} face. The four main portions are thinner than the four sub-portions. The first gate electrode is disposed on the first gate insulating film.

In still another embodiment, a semiconductor device may include, but is not limited to, a semiconductor substrate; an extending semiconductor portion; a gate insulating film; a first gate electrode; a lower diffusion region; an upper diffusion region; an insulating pillar; and a second gate electrode. The extending semiconductor portion extends vertically from the semiconductor substrate. The extending semiconductor portion have a side surface which comprises four main surfaces of {100} face and four sub-surfaces of {110} face. The four sub-surfaces is smaller in area than the four main surfaces. The gate insulating film includes four main portions covering the four main surfaces of {100} face, and four sub-portions covering the four sub-surfaces of {110} face. The four main portions are thinner than the four sub-portions. A first gate electrode is disposed on the first gate insulating film. A lower diffusion region is disposed in the semiconductor substrate. The lower diffusion region is disposed around a base of the extending semiconductor portion. An upper diffusion region is disposed on an upper surface of the extending semiconductor portion. An insulating pillar vertically extends from a surface of an isolation region of the semiconductor substrate. A second gate electrode covers a side surface of the insulating pillar, the second gate electrode being in contact with the first gate electrode.

In an additional embodiment, a method of forming a semiconductor device may include, but not limited to, the following processes. A semiconductor substrate is selectively etched to form a projection which vertically extends from the surface of the semiconductor substrate. The projection has four side surfaces of {110} face. A thermal oxide film is formed on the four side surfaces of {110} face of the projection. The thermal oxide film is removed to form an extending semiconductor portion that extends vertically from the surface of the semiconductor substrate. The extending semiconductor portion has a side surface which comprises four main surfaces of {100} face and four sub-surfaces of {110} face. The four sub-surfaces are smaller in area than the four main surfaces.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating a semiconductor device in accordance with a first preferred embodiment of the present invention;

FIG. 2 is a fragmentary plan view illustrating the semiconductor device of FIG. 1;

FIG. 3 is a diagram illustrating a relationship between normalized stress and normalized current driving capability over area ratio of sub-surface to main-surface;

FIG. 4 is a fragmentary cross sectional elevation view illustrating a semiconductor device in accordance with a second preferred embodiment of the present invention;

FIG. 5A is a fragmentary plan view illustrating a semiconductor device in a step involved in a method of forming the semiconductor device of FIG. 4;

FIG. 5B is a fragmentary cross sectional elevation view illustrating the semiconductor device taken along a B-B′ line of FIG. 5A;

FIG. 6A is a fragmentary plan view illustrating a semiconductor device in a step, subsequent to the step of FIGS. 5A and 5B, involved in a method of forming the semiconductor device of FIG. 4;

FIG. 6B is a fragmentary cross sectional elevation view illustrating the semiconductor device taken along a C-C′ line of FIG. 6A;

FIG. 7A is a fragmentary plan view illustrating a semiconductor device in a step, subsequent to the step of FIGS. 6A and 6B, involved in a method of forming the semiconductor device of FIG. 4;

FIG. 7B is a fragmentary cross sectional elevation view illustrating the semiconductor device taken along a D-D′ line of FIG. 7A;

FIG. 7C is a fragmentary cross sectional elevation view illustrating the semiconductor device taken along an E-E′ line of FIG. 7A;

FIG. 8A is a fragmentary plan view illustrating a semiconductor device in a step, subsequent to the step of FIGS. 7A, 7B and 7C, involved in a method of forming the semiconductor device of FIG. 4;

FIG. 8B is a fragmentary cross sectional elevation view illustrating the semiconductor device taken along an F-F′ line of FIG. 8A;

FIG. 8C is a fragmentary cross sectional elevation view illustrating the semiconductor device taken along a G-G′ line of FIG. 8A;

FIG. 9A is a fragmentary plan view illustrating a semiconductor device in a step, subsequent to the step of FIGS. 8A, 8B and 8C, involved in a method of forming the semiconductor device of FIG. 4;

FIG. 9B is a fragmentary cross sectional elevation view illustrating the semiconductor device taken along an H-H′ line of FIG. 9A;

FIG. 10A is a fragmentary plan view illustrating a semiconductor device in a step, subsequent to the step of FIGS. 9A and 9B, involved in a method of forming the semiconductor device of FIG. 4;

FIG. 10B is a fragmentary cross sectional elevation view illustrating the semiconductor device taken along an line of FIG. 10A;

FIG. 11 is a fragmentary cross sectional elevation view illustrating a semiconductor device in a step, subsequent to the step of FIGS. 10A and 10B, involved in a method of forming the semiconductor device of FIG. 4;

FIG. 12A is a fragmentary cross sectional elevation view illustrating a semiconductor device in a step, subsequent to the step of FIG. 11, involved in a method of forming the semiconductor device of FIG. 4;

FIG. 12B is a fragmentary plan view illustrating the semiconductor device taken along a J-J′ line of FIG. 12A;

FIG. 13A is a fragmentary cross sectional elevation view illustrating a semiconductor device in a step, subsequent to the step of FIGS. 12A and 12B, involved in a method of forming the semiconductor device of FIG. 4;

FIG. 13B is a fragmentary plan view illustrating the semiconductor device taken along a K-K′ line of FIG. 13A;

FIG. 14 is a fragmentary cross sectional elevation view illustrating a semiconductor device in a step, subsequent to the step of FIGS. 13A and 13B, involved in a method of forming the semiconductor device of FIG. 4;

FIG. 15 is a fragmentary cross sectional elevation view illustrating a semiconductor device in a step, subsequent to the step of FIG. 14, involved in a method of forming the semiconductor device of FIG. 4;

FIG. 16 is a fragmentary cross sectional elevation view illustrating a semiconductor device in a step, subsequent to the step of FIG. 15, involved in a method of forming the semiconductor device of FIG. 4;

FIG. 17 is a fragmentary cross sectional elevation view illustrating a semiconductor device in a step, subsequent to the step of FIG. 16, involved in a method of forming the semiconductor device of FIG. 4;

FIG. 18 is a fragmentary cross sectional elevation view illustrating a semiconductor device in a step, subsequent to the step of FIG. 17, involved in a method of forming the semiconductor device of FIG. 4;

FIG. 19 is a fragmentary cross sectional elevation view illustrating a semiconductor device in a step, subsequent to the step of FIG. 18, involved in a method of forming the semiconductor device of FIG. 4;

FIG. 20 is a fragmentary cross sectional elevation view illustrating a semiconductor device in a step, subsequent to the step of FIG. 19, involved in a method of forming the semiconductor device of FIG. 4;

FIG. 21 is a diagram illustrating a characteristic of a drain current to a gate voltage of the semiconductor device of Example 1;

FIG. 22 is a diagram illustrating a relationship between the current driving capability and the area ratio of the semiconductor device of Examples 1 to 5;

FIG. 23 is a diagram illustrating a relationship between a gate leakage of current and an area ratio of the semiconductor device of Examples 1 to 5;

FIG. 24 is a schematic plan view illustrating an example of a layout of pillars over a silicon wafer;

FIG. 25A is a plan view illustrating the pillar 4 shaped in circle in plan view in FIG. 24;

FIG. 25B is a side view illustrating the pillar shaped in circle in plan view in FIG. 24;

FIG. 26A is a plan view illustrating the pillar shaped in rectangle in plan view in FIG. 24; and

FIG. 26B is a side view illustrating the pillar shaped in rectangle in plan view in FIG. 24.

### DETAILED DESCRIPTION OF THE PREFERRED EMBODIMENTS

Before describing the present invention, the related art will be explained in detail with reference to FIGS. 24, 25A, 25B, 26A and 26B, in order to facilitate the understanding of the present invention.

The pillars of the pillar MOS transistors can be typically formed by etching one surface of a silicon wafer. It is necessary to carry out a precise alignment of an etching mask for forming a pillar having a predetermined size at a predetermined position of the wafer.

A reference pattern for alignment of a mask, hereinafter referred to as a reference pattern, is formed. The reference pattern is used to align a photomask that is to be used in later processes. The reference pattern is positioned with reference to a notch. The notch is provided in a silicon wafer.

FIG. 24 is a schematic plan view illustrating an example of a layout of pillars over a silicon wafer.

With reference to FIG. 24, a notch 2 is formed on the outer circumference of a silicon wafer 1 which is shaped in circle in plan view. One surface of the silicon wafer 1 is (100)-face. The notch 2 is directed in <110> direction. The photomask pattern has X-direction line and Y-direction line both of which are directed in <110> direction.

The silicon wafer 1 includes first-half and second-half regions which are separated by a first center line running along the X-direction. The first-half region includes first and second quarter regions which are bounded by a second center line running along the Y-direction. The second-half region includes third and fourth quarter regions which are bounded by the second center line running along the Y-direction. The notch 2 is positioned in the second-half region. The notch 2 is positioned on the second center line running along the Y-direction and on the outer circumference of the silicon wafer 1.

The silicon wafer 1 includes a plurality of pillars 3 in the first-half region and a plurality of pillars 4 in the second-half region. The plurality of pillars 3 is provided in the first-half region opposite to the second-half region in which the notch 2 is provided. Each of the pillars 3 is shaped in rectangle in plan view. In some cases, an array of the plurality of pillars 3 may be, but not limited to, symmetrical with reference to the second center line running along the Y-direction. Each side of each pillar 3 is directed in <110> direction. Each side-face of the pillar 3 is {110} face.

The plurality of pillars 4 is provided in the second-half region in which the notch 2 is positioned. The second-half region is opposite to the first-half region in which the plurality of pillars 3 is positioned. Each of the pillars 4 is shaped in circle in plan view. In some cases, an array of the plurality of pillars 4 may be, but not limited to, symmetrical with reference to the second center line running along the Y-direction. Each side-face of each pillar 4 has various crystal faces.

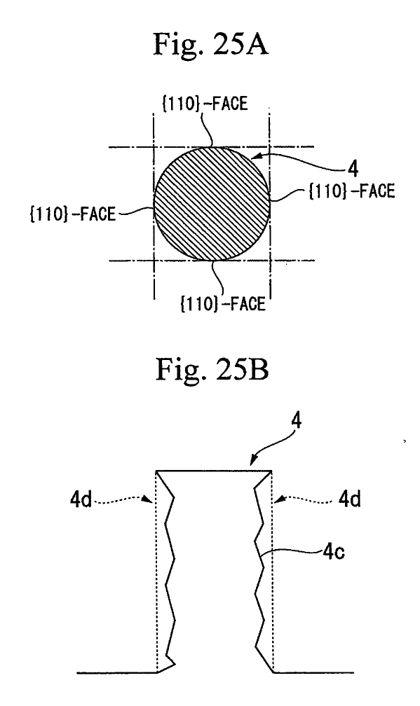

FIG. 25A is a plan view illustrating the pillar 4 shaped in circle in plan view in FIG. 24. FIG. 25B is a side view illustrating the pillar 4 shaped in circle in plan view in FIG. 24.

In FIG. 25A, the dotted line shows the {110} face. The side face of the pillar 4 has a residual small part of {110} face.

After the pillar 4 is formed, then a thermal oxide film is formed on the side surface of the pillar 4. The thermal oxide film will serve as a protecting film that prevents ions from being implanted into the side surface of the pillar 4 when an ion-implantation process is carried out to form lower diffusion layers in the wafer.

After the lower diffusion layers have been formed, the thermal oxide film needs to be removed in order to perform gate oxidation process. The side surface of the pillar 4 shaped in circle in plan view has various plan-directions. Removal of the thermal oxide film using chemicals and cleaning process for cleaning the pillar 4 prior to the gate oxidation may erode the {110} face of the pillar 4. The original {110} face 4d of the side surface of the pillar 4 may be eroded toward the central axis of the pillar 4. As a result, the original {110} face 4d becomes irregular side surface 4c as shown in FIG. 25B.

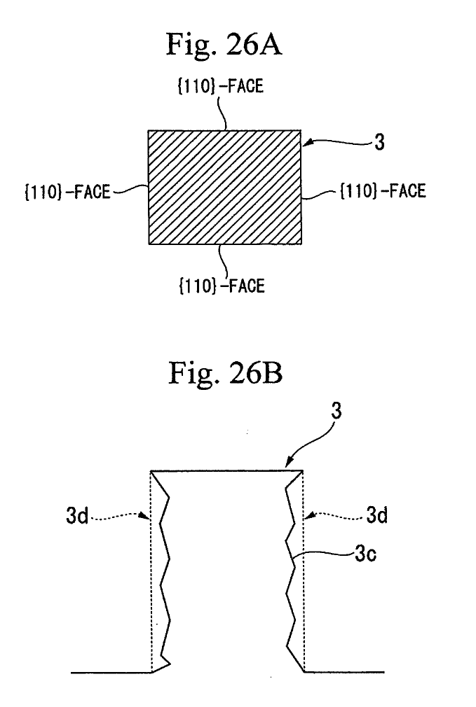

FIG. 26A is a plan view illustrating the pillar 4 shaped in rectangle in plan view in FIG. 24. FIG. 26B is a side view illustrating the pillar 4 shaped in rectangle in plan view in FIG. 24.

As shown in FIG. 26A, the pillar 3 has four side-surfaces 3d of {110} face. The side-surfaces 3c are mostly {110} face. After the pillar 3 is formed, then a thermal oxide film is formed on the side surface of the pillar 3. The thermal oxide film will serve as a protecting film that prevents ions from being implanted into the side surface of the pillar 3 when an ion-implantation process is carried out to form lower diffusion layers in the wafer.

After the lower diffusion layers have been formed, the thermal oxide film needs to be removed in order to perform gate oxidation process. Removal of the thermal oxide film using chemicals and cleaning process for clearing the pillar 3 prior to the gate oxidation may erode the {110} face 3d of the pillar 3. The original {110} face 3d of the side surface of the pillar 3 may be eroded toward the central axis of the pillar 3. As a result, the original {110} face 3d becomes irregular side surface 3c as shown in FIG. 26B.

As described above, the pillars 3 and 4 can be eroded by chemicals. The {110} face 3d on the side surface of the pillar 3 becomes irregular side surface 3c. The {110} face 4d on the side surface of the pillar 4 becomes irregular side surface 4c. A gate insulating film is formed, which covers the irregular side surface 3c or 4c of the pillar 3 or 4. As a result, an irregular interface is formed between the gate insulating films and the irregular side surface 3c or 4c of the pillars 3 and 4. The irregular interface will increase the effective channel length of the pillar MOS transistor. The increase of the effective channel length will reduce current driving capability by about 20% to about 30% of the pillar MOS transistor. Further, the irregular interface will increase the field concentration, thereby reducing the reliability of the gate insulating film.

The pillar 3 shaped in rectangle in plan view has the side surfaces 3c of {110} face. Thus, the pillar 3 has four corners of substantially {100} face. The gate oxide film is formed on the pillar 3 by the thermal oxidation process. The thermal oxidation rate of the {100} face is slower than that of the {110} face. The gate oxide film at the corners of the pillar 3 is thinner than the gate oxide film on the side surface 3c of the pillar 3. A leakage of current may be caused at the corners of the pillar 3. There have been required to reduce the thickness of the gate oxide film of the pillar MOS transistor for the purpose of improving the current driving capability. To satisfy this requirement, this leakage of current may become more serious.

As described above, the pillars 3 and 4 have the irregular side surfaces 3c and 4c which are different from the {110} faces 3d and 4d. The irregular interface between the gate insulating film and the irregular side surface 3c or 4c of the pillar 3 or 4 will increase the effective channel length of the pillar MOS transistor, thereby reducing current driving capability and increasing the field concentration.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

In one embodiment, a semiconductor device may include, but is not limited to, a semiconductor substrate, and an extending semiconductor portion that extends vertically from the semiconductor substrate. The extending semiconductor portion has a side surface which comprises four main surfaces of {100} face and four sub-surfaces of {110} face. The four sub-surfaces are smaller in area than the four main surfaces.

In some cases, a total area of the four sub-surfaces may be in the range of 10% to 30% of a total area of the main surfaces.

In some cases, each of the four sub-surfaces may be between two adjacent main surfaces of the four main surfaces, and each of the four main surfaces may be between two adjacent sub-surfaces of the four sub-surfaces.

In some cases, the semiconductor device may further include, but is not limited to, a gate insulating film that comprises four main portions covering the four main surfaces of {100} face, and four sub-portions covering the four sub-surfaces of {110} face.

In some cases, the four main portions may be thinner than the four sub-portions.

In some cases, the extending semiconductor portion may have a shape defined by eighth sides and eight angles in plan view.

In some cases, first two of the four main surfaces may be positioned in first opposing sides and second two of the four main surfaces are positioned in second opposing sides, and the first two of the four main surfaces may be greater in width than the second two of the four main surfaces.

In some cases, the second two of the four main surfaces may be greater in width than the four sub-surfaces.

In some cases, the semiconductor device may further include, but is not limited to, a lower diffusion region in the semiconductor substrate, the lower diffusion region being disposed around a base of the extending semiconductor portion; an upper diffusion region on an upper surface of the extending semiconductor portion; a first gate insulating film covering the side surface of the extending semiconductor portion; and a first gate electrode on the first gate insulating film.

In some cases, the first gate insulating film may include thicker portions covering the four main surfaces and thinner portions covering the four sub-surfaces. The thicker portions may be thicker than the thinner portions.

In some cases, a channel length may be vertical to a surface of the semiconductor substrate.

In some cases, the semiconductor device may further include, but is not limited to, an insulating pillar vertically extending from a surface of an isolation region of the semiconductor substrate; and a second gate electrode covering a side surface of the insulating pillar, the second gate electrode being in contact with the first gate electrode.

In some cases, the semiconductor device may further include, but is not limited to, an interlayer insulating film that covers the extending semiconductor portion, the insulating pillar, and the first and second gate electrodes; a first plug in the interlayer insulating film, the first plug being connected to the upper diffusion region; a second plug in the interlayer insulating film, the second plug being connected to a distal portion of the second gate electrode, the distal portion being distal from the first gate electrode; and a third plug in the interlayer insulating film, the third plug being connected to the lower diffusion region.

In some cases, the extending semiconductor portion may be made of the same semiconductor of the semiconductor substrate.

In another embodiment, a semiconductor device may include, but is not limited to, a semiconductor substrate, an extending semiconductor portion, a gate insulating film and a first gate electrode. The extending semiconductor portion extends vertically from the semiconductor substrate. The extending semiconductor portion have a side surface which comprises four main surfaces of {100} face and four sub-surfaces of {110} face. A total area of the four sub-surfaces is smaller than a total area of the four main surfaces. A gate insulating film includes four main portions covering the four main surfaces of {100} face, and four sub-portions covering the four sub-surfaces of {110} face. The four main portions are thinner than the four sub-portions. The first gate electrode is disposed on the first gate insulating film.

In some cases, the total area of the four sub-surfaces is in the range of 10% to 30% of the total area of the main surfaces.

In some cases, the semiconductor device may further include, but is not limited to, a lower diffusion region in the semiconductor substrate, the lower diffusion region being disposed around a base of the extending semiconductor portion; and an upper diffusion region on an upper surface of the extending semiconductor portion.

In some cases, the semiconductor device may further include, but is not limited to, an insulating pillar vertically extending from a surface of an isolation region of the semiconductor substrate; a second gate electrode covering a side surface of the insulating pillar, the second gate electrode being in contact with the first gate electrode; an interlayer insulating film that covers the extending semiconductor portion, the insulating pillar, and the first and second gate electrodes; a first plug in the interlayer insulating film, the first plug being connected to the upper diffusion region; a second plug in the interlayer insulating film, the second plug being connected to a distal portion of the second gate electrode, the distal portion being distal from the first gate electrode; and a third plug in the interlayer insulating film, the third plug being connected to the lower diffusion region.

In still another embodiment, a semiconductor device may include, but is not limited to, a semiconductor substrate; an extending semiconductor portion; a gate insulating film; a first gate electrode; a lower diffusion region; an upper diffusion region; an insulating pillar; and a second gate electrode. The extending semiconductor portion extends vertically from the semiconductor substrate. The extending semiconductor portion have a side surface which comprises four main surfaces of {100} face and four sub-surfaces of {110} face. The four sub-surfaces is smaller in area than the four main surfaces. The gate insulating film includes four main portions covering the four main surfaces of {100} face, and four sub-portions covering the four sub-surfaces of {110} face. The four main portions are thinner than the four sub-portions. A first gate electrode is disposed on the first gate insulating film. A lower diffusion region is disposed in the semiconductor substrate. The lower diffusion region is disposed around a base of the extending semiconductor portion. An upper diffusion region is disposed on an upper surface of the extending semiconductor portion. An insulating pillar vertically extends from a surface of an isolation region of the semiconductor substrate. A second gate electrode covers a side surface of the insulating pillar, the second gate electrode being in contact with the first gate electrode.

In some cases, the total area of the four sub-surfaces may be in the range of 10% to 30% of the total area of the main surfaces.

In an additional embodiment, a method of forming a semiconductor device may include, but not limited to, the following processes. A semiconductor substrate is selectively etched to form a projection which vertically extends from the surface of the semiconductor substrate. The projection has four side surfaces of {110} face. A thermal oxide film is formed on the four side surfaces of {110} face of the projection. The thermal oxide film is removed to form an extending semiconductor portion that extends vertically from the surface of the semiconductor substrate. The extending semiconductor portion has a side surface which comprises four main surfaces of {100} face and four sub-surfaces of {110} face. The four sub-surfaces are smaller in area than the four main surfaces.

In some cases, the thermal oxide film is removed by a wet-etching process.

In some cases, the method may further include, but is not limited to, the following processes. A gate insulating film is formed which covers the four main surfaces of {100} face and the four sub-surfaces of {110} face. A gate electrode is formed which covers the gate insulating film.

In some cases, the method may further include, but is not limited to, the following processes. After the thermal oxide film is formed, an ion is implanted into the semiconductor substrate to form a lower diffusion region in the semiconductor substrate. The lower diffusion region is disposed around the base of the projection. After the gate electrode is formed, an ion is implanted into the top of the extending semiconductor portion to form an upper diffusion layer at the top of the extending semiconductor portion.

### First Embodiment

### (Semiconductor Device)

First, the semiconductor device which is a first embodiment of the invention will be described.

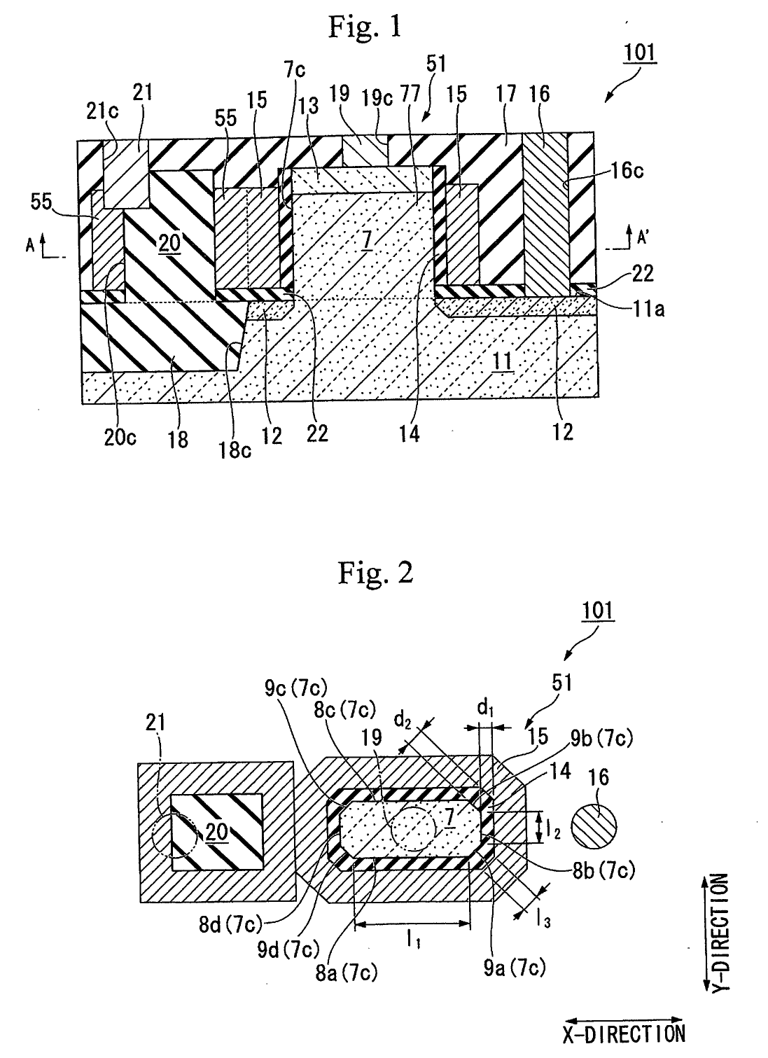

FIG. 1 is a fragmentary cross-sectional elevation view illustrating a semiconductor device in accordance with a first embodiment of the invention.

As shown in FIG. 1, a semiconductor device 101 includes a semiconductor substrate 11 and a pillar MOS transistor 51 over the semiconductor substrate 11. The semiconductor substrate 11 may be made of silicon. The pillar MOS transistor 51 includes an extending portion 7 which extends upwardly from a surface 11a of the substrate 11. The surface 11a of the substrate 11 is (100) face.

The semiconductor device 101 includes an upper diffusion layer 13. The upper diffusion layer 13 is disposed at the top of the extending portion 7. The semiconductor device 101 includes a lower diffusion layer 12. The lower diffusion layer 12 is disposed in the semiconductor substrate 11. The lower diffusion layer 12 is disposed around the base of the extending portion 7. The semiconductor device 101 includes a gate insulating film 14. The gate insulating film 14 covers a side surface 7c of the extending portion 7. The gate insulating film 14 extends vertically from the surface 11a of the substrate 11. The semiconductor device 101 includes a gate electrode 15. The gate electrode 15 covers the gate insulating film 14. The semiconductor device 101 includes the pillar MOS transistor 51 having the structural elements described above.

The lower diffusion layer 12 and the upper diffusion layer 13 may serve as source and drain regions of the pillar MOS transistor 51. The pillar MOS transistor 51 includes a channel 77 which is inside the extending portion 7. The direction of the channel 77 is vertical to the surface 11a of the substrate 11. The channel 77 is parallel to the side surface 7c of the extending portion 7. The channel 77 extends between the lower diffusion layer 12 and the upper diffusion layer 13. The channel 77 is caused by applying a predetermined voltage to the gate electrode 15, so that an electrical conduction can be obtained through the channel 77 between the lower diffusion layer 12 and the upper diffusion layer 13.

The semiconductor device 101 includes an interlayer insulating film 17 which covers the pillar MOS transistor 51. The interlayer insulating film 17 has a hole 16c which partially exposes the lower diffusion layer 12. The lower diffusion layer 12 is disposed around the base of the extending portion 7. A third plug electrode 16 is formed so that the third plug electrode 16 fills the hole 16c. The third plug electrode 16 allows supply of a potential to the lower diffusion layer 12.

The interlayer insulating film 17 further has a hole 19c, which partially exposes the upper diffusion layer 13 at the top of the extending portion 7. A first plug electrode 19 is formed so that the first plug electrode 19 fills the hole 19c. The first plug electrode 19 allows supply of a potential to the upper diffusion layer 13.

The substrate 11 has a groove 18c. The groove 18c is filled with an insulating material such as silicon oxide. An isolation region 18 is disposed in the groove 18c. The isolation region 18 is made of an insulating material such as silicon oxide. The isolation region 18 electrically isolates a plurality of pillar MOS transistors 51 from each other.

The semiconductor device 101 includes a dummy pillar 20. The dummy pillar 20 is disposed over the isolation region 18. The dummy pillar 20 may be made of an insulating material such as silicon oxide. The semiconductor device 101 includes a gate electrode 55. The gate electrode 55 covers a side surface 20c of the dummy pillar 20. The gate electrode 55 covering the side surface 20c of the dummy pillar 20 is electrically connected to the gate electrode 15 that covers the side surfaces 7c of the extending portion 7.

The dummy pillar 20 is not limited to the insulating materials such as silicon oxide. In other cases, the dummy pillar 20 may be made of semiconductor materials such as silicon. As shown in FIG. 1, the gate electrode 55 may be separated from the gate electrode 15. Preferably, the gate electrodes 15 and 55 may be made of the same material. The gate electrodes 15 and 55 may be united with each other. The gate electrodes 15 and 55 may preferably have the same thickness which is defined as a dimension in the direction parallel to the surface 11a of the substrate 11. The dummy pillar 20 and the extending portion 7 may be distanced from each other by a distance which is smaller than the double of the thickness of each of the gate electrodes 15 and 55. The upper surface of the isolation region 18 has the same level as the surface 11a of the substrate 11. A part of the side surface 18c of the isolation region 18 is positioned in plan view between the dummy pillar 20 and the extending portion 7. The upper surface of the dummy pillar 20 extending upwardly from the isolation region 18 has the same level as the upper surface of the extending portion 7.

A hole 21c is provided in the interlayer insulating film 17. The gate electrode 55 is exposed through the hole 21c. The hole 21c is positioned over the gate electrode 55 and the dummy pillar 20. In plan view, the hole 21c is positioned in the distal side of the dummy pillar 20 from the transistor. The hole 21c is positioned in the opposite side of the dummy pillar 20 to the extending portion 7 as a part of the transistor. A second plug electrode 21 is formed so that the second plug electrode 21 fills the hole 21c. The second plug electrode 21 allows supply of a potential to the gate electrode 15 through the gate electrode 55.

A lower insulation film 22 is formed. The lower insulation film 22 covers the surface 11a of the substrate 11, and covers the insulating materials filled in the isolation region 18. The lower insulation film 22 is bonded to the gate insulating film 14 in the base of the extending portion 7. The gate electrode 15 is electrically insulated from the lower diffusion layer 12 by the lower insulation film 22.

The lower diffusion layer 12 is disposed around the base of the extending portion 7. The lower diffusion layer 12 covers the surface 11a of the substrate 11. It is possible to supply a potential through a well layer (not shown) to the substrate 11 under the lower diffusion layer 12.

FIG. 2 is a fragmentary plane view taken along an A-A′ line of FIG. 1. The interlayer insulating film 17 is not shown.

As shown in FIG. 2, the extending portion 7 is octagonal in plan view. The side surfaces 7c of the extending portion 7 may include four main surfaces 8a, 8b, 8c, and 8d and four sub-surfaces 9a, 9b, 9c, and 9d. The main surfaces 8a and 8c are opposite to each other. The main surfaces 8b and 8d are opposite to each other. The four sub-surfaces 9a, 9b, 9c, and 9d are between the main surfaces 8a, 8b, 8c, and 8d. The sub-surface 9a is between the main surfaces 8a and 8b. The sub-surface 9b is between the main surfaces 8b and 8c. The sub-surface 9c is between the main surfaces 8c and 8d. The sub-surface 9d is between the main surfaces 8d and 8a. The main surfaces 8a, 8b, 8c, and 8d are the {100} face perpendicular to the <100> orientation. The sub-surfaces 9a, 9b, 9c, and 9d are the {110} face perpendicular to the <110> orientation. The side surfaces 7c of the extending portion 7 includes the four main surfaces 8a, 8b, 8c, and 8d and the four sub-surfaces 9a, 9b, 9c, and 9d. The main surfaces 8a and 8c are the {100} face perpendicular to a <100> orientation which is parallel to the Y-direction in FIG. 2. The main surfaces 8b and 8d are the {100} face perpendicular to a <100> orientation which is parallel to the X-direction in FIG. 2. The four sub-surfaces 9a, 9b, 9c, and 9d have an angle of 45 degrees to the <100> orientation. The four sub-surfaces 9a, 9b, 9c, and 9d are positioned at four corners of the rectangle having the sour sides of the main surfaces 8a, 8b, 8c, and 8d. The upper surface of the extending portion 7 is the {100} face which is the same as the surface 11a of the substrate 11.

The width l₁ of the main surface 8a is the same as the width l₁ of the main surface 8c. The width l₂ of the main surface 8b is the same as the width l₂ of the main surface 8d. The width l₂ is shorter than the width l₁. The sub-surfaces 9a, 9b, 9c, and 9d have the same width l₃. The width l₃ is shorter than the width l₂.

The heights of the main surfaces 8a, 8b, 8c, and 8d, and the sub-surfaces 9a, 9b, 9c, and 9d are the same. For this reason, the area of the main surface 8a and the area of the main, surface 8c are the same. The areas of the main surface 8b and the area of the main surface 8d are the same. The areas of the sub-surfaces 9a, 9b, 9c, and 9d are the same. The main surfaces 8a and 8c have the largest area in the main surfaces 8a, 8b, 8c, and 8d and the sub-surfaces 9a, 9b, 9c, and 9d. The sub-surfaces 9a, 9b, 9c, and 9d have the smallest area in the main surfaces 8a, 8b, 8c, and 8d and the sub-surfaces 9a, 9b, 9c, and 9d.

The area in total of the four sub-surfaces 9a, 9b, 9c, and 9d is preferably in the range of 10% to 30% of the area in total of the four main surfaces 8a, 8b, 8c, and 8d. The ratio in total area of the sub-surfaces 9a, 9b, 9c, and 9d to the main surfaces 8a, 8b, 8c, and 8d is in the range of 10% to 30%. This ratio will be referred to as the area ratio. The total area of the sub-surfaces 9a, 9b, 9c, and 9d is smaller than the total area of the main surfaces 8a, 8b, 8c, and 8d, wherein the sub-surfaces 9a, 9b, 9c, and 9d are likely to be irregular surfaces as compared to the main surfaces 8a, 8b, 8c, and 8d. Reducing the area ratio will suppress the surface roughness of the side surface 7c of the extending portion 7.

The gate insulating film 14 is formed so as to cover the side surfaces 7c of the extending portion 7. The gate electrode 15 is formed so as to cover the gate insulating film 14. The thickness d₂ of the gate insulating film 14 on the sub-surfaces 9a, 9b, 9c, and 9d is thicker than the thickness d₁ of the gate insulating film 14 on the main surfaces 8a, 8b, 8c, and 8d.

It is preferable that the thickness d₂ of the gate insulating film 14 on the sub-surfaces 9a, 9b, 9c, and 9d is thicker than the thickness d₁ of the gate insulating film 14 on the main surfaces 8a, 8b, 8c, and 8d. The thickness d₂ of the gate insulating film 14 on the sub-surfaces 9a, 9b, 9c, and 9d is thicker, whereby it is possible to reduce the field concentration at the sub-surfaces 9a, 9b, 9c, and 9d which are likely to be rougher and to improve reliability of the pillar MOS transistor 51.

The dummy pillar 20 which is shaped in rectangle in plan view is formed adjacent to the extending portion 7. The gate electrode 55 is formed so as to cover the side surface 20c of the dummy pillar 20. The gate electrode 55 is electrically connected to the gate electrode 15 covering the side surfaces of the extending portion 7.

The third plug electrode 16 which is circular in plan view is formed in the side of the extending portion 7, opposite to the dummy pillar 20. The extending portion 7 may be interposed between the dummy pillar 20 and the third plug electrode 16. The dummy pillar 20, the extending portion 7 and the third plug electrode 16 may be aligned in the X-direction as shown in FIG. 2. Namely, the dummy pillar 20, the extending portion 7 and the third plug electrode 16 may be positioned on an axis which is parallel to the X-direction as shown in FIG. 2.

In other cases, the dummy pillar 20, the extending portion 7 and the third plug electrode 16 may be aligned in the Y-direction as shown in FIG. 2. The extending portion 7 may be interposed between the dummy pillar 20 and the third plug electrode 16. Namely, the dummy pillar 20, the extending portion 7 and the third plug electrode 16 may be positioned on an axis which is parallel to the Y-direction as shown in FIG. 2.

In other cases, the dummy pillar 20 may be positioned around the extending portion 7, provided that the distance between the dummy pillar 20 the extending portion 7 is smaller than the double of the thickness of the gate electrodes 15 and 55. The dummy pillar 20 the extending portion 7 and the third plug electrode 16 may be unaligned.

As shown in FIG. 2, the first plug electrode 19 which is circular in plan view is formed so as to come into contact with the extending portion 7. The second plug electrode 21 which is circular in plan view is formed so as to come into partial contact with the gate electrode 55.

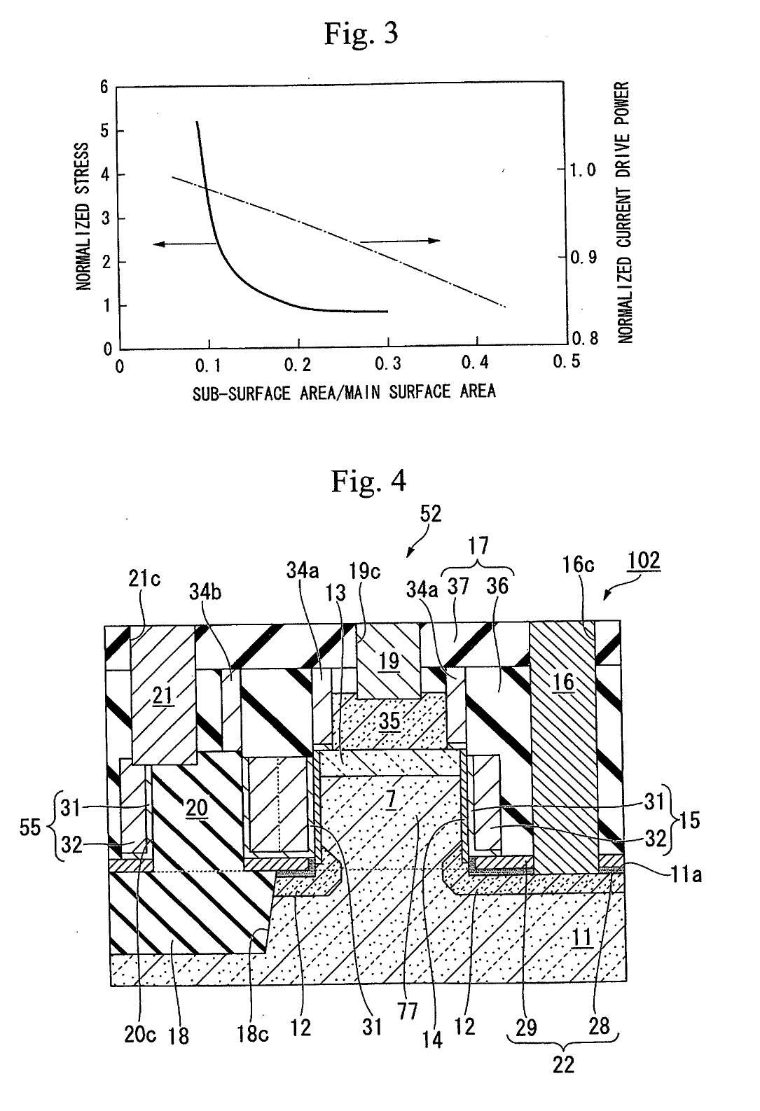

FIG. 3 is a graph illustrating a relationship between normalized stress and normalized current driving capability. FIG. 3 illustrates the area ratio of the pillar MOS transistor 51 of the semiconductor device 101. FIG. 3 illustrates the dependencies of the normalized stress and the normalized current driving capability upon the area ratio dependency.

As shown in FIG. 3, it is preferable that the area ratio is in the range of 0.1 to 0.3. It is preferable that the total area of the sub-surfaces is in the range of 10% to 30% of the total area of the main surfaces. As a result, the normalized stress will be in the range of 1 to 5 and the normalized current driving capability will be in the range of 0.9 to 0.98.

When the area ratio is less than 0.1, the sub-surfaces 9a, 9b, 9c, and 9d is too small to be confirmed, so that the curvature is too small to determine the face orientation of the sub-surfaces 9a, 9b, 9c, and 9d. For this reason, it is difficult to reduce the field concentration in the sub-surfaces 9a, 9b, 9c, and 9d. The filed concentration is caused from the gate electrode 15 into the sub-surfaces 9a, 9b, 9c, and 9d. The stress from the gate electrode 15 is concentrated. As a result, crystal defects of silicon can be caused.

When the area ratio exceeds 0.3, it is difficult to suppress the lowering of the normalized current driving capability within 10%. As a result, device characteristic variations are too large.

The semiconductor device 101 includes the substrate 11, the extending portion 7 which extends in a vertical direction from the surface 11a of the substrate 11, the upper diffusion layer 13 at the top of the extending portion 7, the lower diffusion layer 12 around the base of the extending portion 7, the gate insulating film 14 covering the side surfaces 7c of the extending portion 7, and the gate electrode 15 covering the gate insulating film 14. The semiconductor device 101 includes the pillar MOS transistor 51 with the channel which is formed in the above-mentioned vertical direction. In the semiconductor device, the extending portion 7 is octagonal in plan view. The side surfaces 7c of the extending portion 7 may be four main surfaces 8a,8b, 8c, and 8d of the {100} face, and four sub-surfaces 9a, 9b, 9c, and 9d of the {110} face. The four sub-surfaces 9a, 9b, 9c, and 9d have smaller areas than the main surfaces 8a, 8b, 8c, and 8d, thereby reducing the surface roughness of the side surfaces 7c of the extending portion 7. In the semiconductor device, even when the gate oxide film 14 is formed so as to cover the side surfaces 7c, the effective channel length is not increased. Thus it is possible to suppress lowering of the current driving capability of the pillar MOS transistor 51. It is possible to prevent the increase in the leakage current of the gate insulating film 14, and to prevent lowering of the ON current. As a result, it is possible to provide the pillar MOS transistor having high current driving capability in a low leakage of current.

The semiconductor device 101 is configured such that the area in total of the four sub-surfaces 9a, 9b, 9c, and 9d is in the range of 10% to 30% of the area in total of the four main surfaces 8a, 8b, 8c, and 8d, thereby reducing the surface roughness of the side surfaces 7c of the extending portion 7. In the semiconductor device, even when the gate oxide film 14 is formed so as to cover the side surfaces 7c, the effective channel length is not increased, and thus it is possible to suppress lowering of the current driving capability of the pillar MOS transistor 51.

The semiconductor device 101 is configured such that the gate insulating film 14 on the sub-surfaces 9a, 9b, 9c, and 9d is thicker than the gate insulating film 14 on the main surfaces 8a, 8b, 8c, and 8d, whereby when the gate oxide film 14 is formed so as to cover the side surfaces 7c. It is possible to suppress the influence of the surface roughness of the sub-surfaces 9a, 9b, 9c, and 9d of the side surface 7c of the extending portion 7. It is possible to reduce the field concentration in the sub-surfaces 9a, 9b, 9c, and 9d. It is possible to improve reliability of the current driving capability of the pillar MOS transistor 51.

### Second Embodiment

### (Semiconductor Device)

A semiconductor device will be described in accordance with a second embodiment of the invention.

FIG. 4 is a schematically cross-sectional view illustrating another example of the semiconductor device in accordance with an embodiment of the invention. The same elements as the elements as shown in the first embodiment are denoted with the same reference numerals.

As shown in FIG. 4, a semiconductor device 102 includes a substrate 11, and a extending portion 7 which extends in a vertical direction from the surface 11a of the {100} face of the substrate 11.

The semiconductor device 102 includes an upper diffusion layer 13. The upper diffusion layer 13 is disposed at the top portion of the extending portion 7. The semiconductor device 102 includes a lower diffusion layer 12. The lower diffusion layer 12 is disposed around the base of the extending portion 7. The semiconductor device 102 includes a gate insulating film 14 covering the side surfaces 7c. The semiconductor device 102 includes a gate electrode 15 covering the gate insulating film 14. The semiconductor device 102 includes a pillar MOS transistor 51 of those elements. A channel 77 is formed in the inside of the extending portion 7 in a direction perpendicular to the surface 11a of the substrate 11, by applying a predetermined voltage to the gate electrode 15 of the pillar MOS transistor 51.

An interlayer insulating film 17 including stacks of interlayer insulating films 36 and 37 is formed. The interlayer insulating film 17 covers the pillar MOS transistor 51.

A hole 16c is provided in the interlayer insulating film 17 so as to partially expose the lower diffusion layer 12 around the base of the extending portion 7. A third plug electrode 16 is formed so as to fill the hole 16c. The third plug electrode 16 allows supply of a potential to the lower diffusion layer 12.

A plug 35 which is made of a silicon region formed by epitaxial growth is provided at the top of the extending portion 7.

A hole 19c is provided in the interlayer insulating film 17 so as to partially expose the plug 35 at the top of the extending portion 7, and a first plug electrode 19 is formed so as to fill in a hole 19c. The first plug electrode 19 allows supply of a potential to the upper diffusion layer 13 through the plug 35.

A sidewall 34a is provided so as to surround the plug 35. In addition, a sidewall 34b is also provided at the top of a dummy pillar 20. The sidewalls 34a and 34b may be made of silicon nitride having a high strength, thereby increasing the rigidity of the semiconductor device.

A groove 18c is provided in the substrate 11. Insulating materials such as silicon oxide are filled in the groove 18c. An isolation region 18 is formed which electrically isolate a plurality of pillar MOS transistors 51 from each other.

A dummy pillar 20 is formed in the isolation region 18. The gate electrode 55 is formed so as to cover the side surface 20c of the dummy pillar 20. The gate electrode 55 is electrically connected to the gate electrode 15 covering the side surfaces 7c of the extending portion 7.

A hole 21c is provided in the interlayer insulating film 17 so as to partially expose the gate electrode 55 to the top of the dummy pillar 20. A second plug electrode 21 is formed so as to fill in the hole 21c. The second plug electrode 21 allows supply of a potential to the gate electrode 15 through the gate electrode 55.

A lower insulation film 22 including stacks of silicon oxide films 28 and 29 is formed so as to cover the surface 11a of the substrate 11. The silicon oxide film 29 of the lower insulation film 22 covers insulating materials filled in the isolation region 18.

The lower insulation film 22 is connected to the gate insulating film 14 in the base of the extending portion 7. The gate electrode 15 is electrically insulated from the lower diffusion layer 12 by the lower insulation film 22.

The lower diffusion layer 12 is formed. The lower diffusion layer 12 extends beneath the surface 11a of the substrate 11. The lower diffusion layer 12 extends around the base of the extending portion 7 and inside the extending portion 7. It is possible to supply a potential through a well layer (not shown) to the substrate 11 under the lower diffusion layer 12.

The gate electrode 15 includes a substantially cylindrical titanium nitride film 31 so as to cover the side surfaces 7c of the extending portion 7. The gate electrode 15 also includes a cylindrical tungsten film 32 so as to cover the titanium nitride film 31. The side of the titanium nitride film 31 closer to the substrate 11 is substantially L-shaped in cross-sectional view so as to partially cover the upper part of the lower insulation film 22.

The gate electrode 55 includes the substantially cylindrical titanium nitride film 31 so as to cover the side surface 20c of the dummy pillar 20. The gate electrode 55 includes the cylindrical tungsten film 32 so as to cover the titanium nitride film 31. The side, closer to the substrate 11, of the titanium nitride film 31 is substantially L-shaped in cross-sectional view so as to partially cover the upper part of the lower insulation film 22.

### Method of Manufacturing the Semiconductor Device:

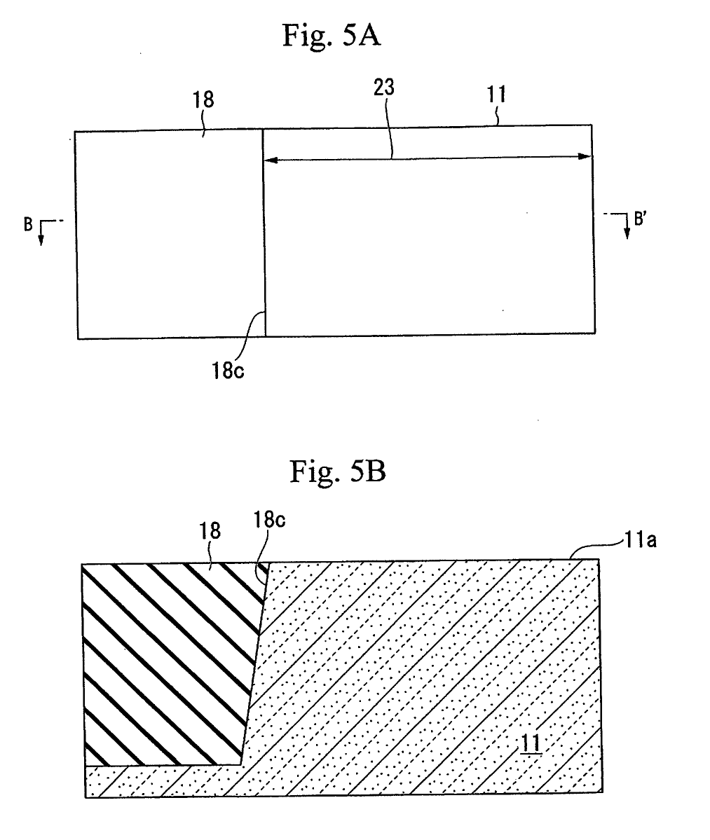

An example of a method of manufacturing the semiconductor device will be described in accordance with an embodiment of the invention. FIGS. 5 to 20 are views illustrating an example of the method of manufacturing the semiconductor device 102 in accordance with this embodiment of the invention.

FIGS. 5A and 5B are views when an active region 23 is formed in the substrate 11. FIG. 5A is a plan view, and FIG. 5B is a cross-sectional view taken along the B-B′ line of FIG. 5A.

The groove 18c is formed in a predetermined region of the substrate 11 using an etching method. As the substrate 11, for example, a p-type silicon substrate is used, and the depth of the groove 18c is for example 300 nm.

Insulating materials such as a silicon oxide film are filled in the groove 18c, and the isolation region 18 as shown in FIG. 5 is formed.

Ion implantation up to the depth of 500 nm from the surface 11a of the substrate 11 is performed in the substrate 11 of a region isolated by the isolation region 18 so that the boron concentration becomes substantially 2×10¹⁷/cm³, and the region isolated by the isolation region 18 is formed to be the active region 23.

A thermal oxide film 24 made of a silicon oxide film having a thickness of 5 nm is formed on the surface 11a of the substrate 11 of the active region 23 by a thermal oxidation method.

A silicon nitride film 25 having a thickness of 100 nm is formed so as to cover the thermal oxide film 24 and the isolation region 18 by a CVD (Chemical Vapor Deposition) method.

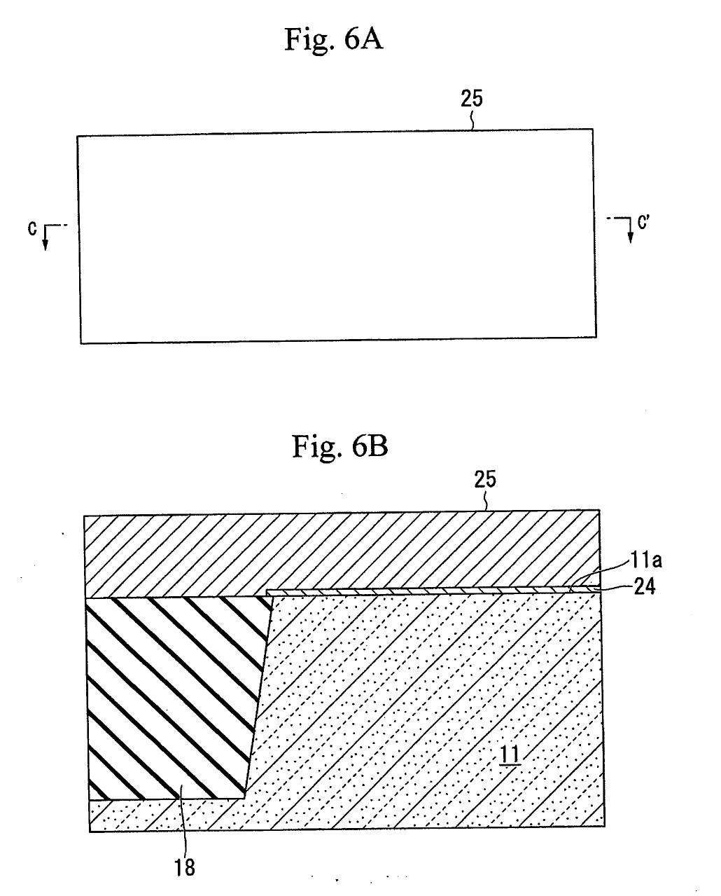

FIGS. 6A and 6B are views when the silicon nitride film 25 is formed in the substrate 11. FIG. 6A is a plan view, and FIG. 6B is a cross-sectional view taken along the C-C′ line of FIG. 6A.

A resist is applied so as to cover the silicon nitride film 25. After the resist is dried, an exposure process is carried out using the mask, and then a line-shaped resist mask 26 is formed.

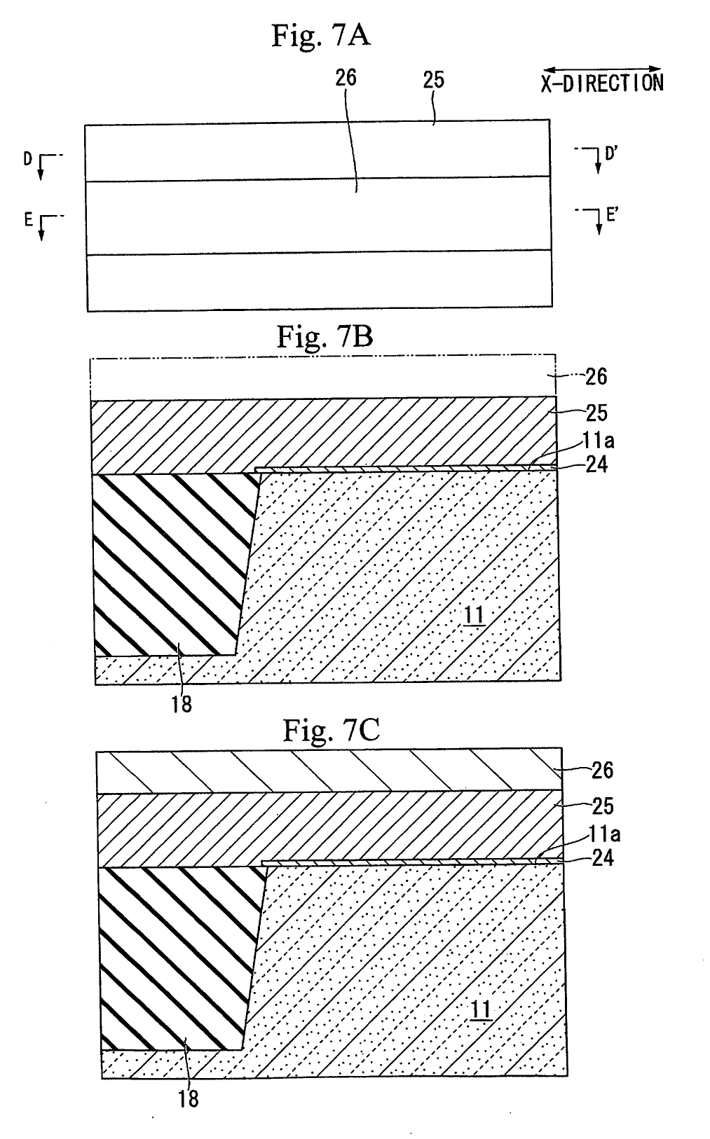

FIGS. 7A to 7C are views when the resist mask 26 is formed. FIG. 7A is a plan view. FIG. 7B is a cross-sectional view taken along the D-D′ line of FIG. 7A. FIG. 7C is a cross-sectional view taken along the E-E′ line of FIG. 7A. The line of the resist mask 26 is formed along the <100> direction (hereinafter, X-direction) of a silicon wafer.

The exposed portion of the silicon nitride film 25 is removed by a dry-etching process using the resist mask 26, so that the thermal oxide film 24 is exposed.

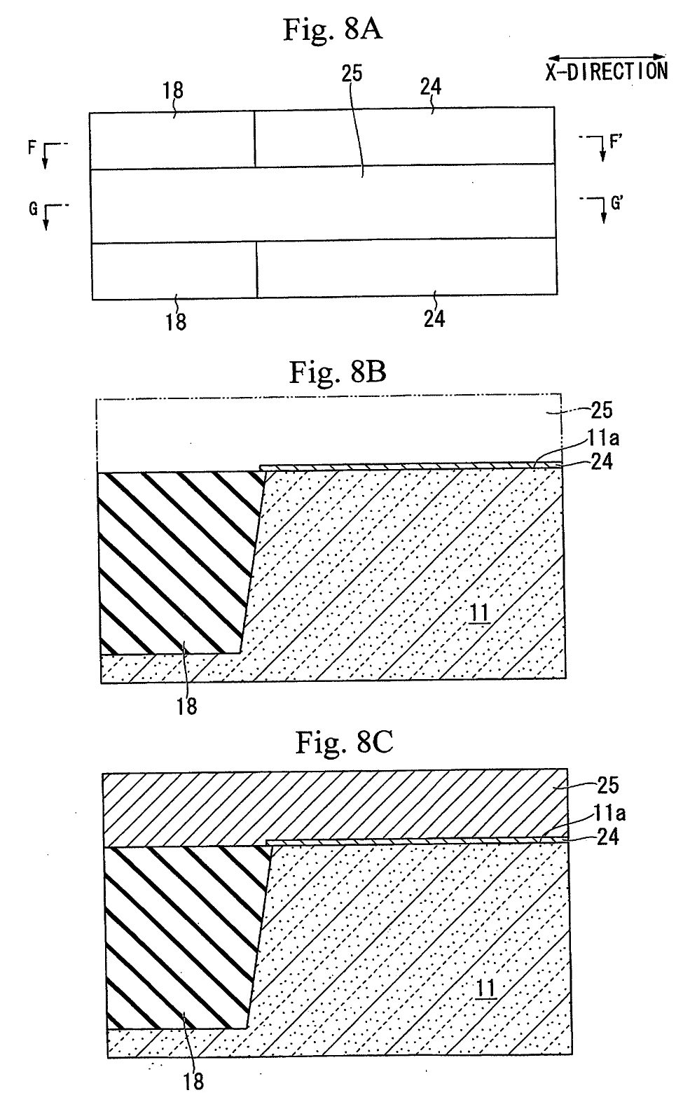

The resist mask 26 is removed, and then the line-shaped silicon nitride film 25 as shown in FIGS. 8A to 8C is formed.

FIGS. 8A to 8C are views when the line-shaped silicon nitride film 25 is formed. FIG. 8A is a plan view. FIG. 8B is a cross-sectional view taken along the F-F′ line of FIG. 8A. FIG. 8C is a cross-sectional view taken along the G-G′ line of FIG. 8A.

A resist is applied so as to cover the thermal oxide film 24 and the silicon nitride film 25. After the resist is dried, an exposure process is carried out using the mask, and then two line-shaped resist masks 27a and 27b having different line widths are formed.

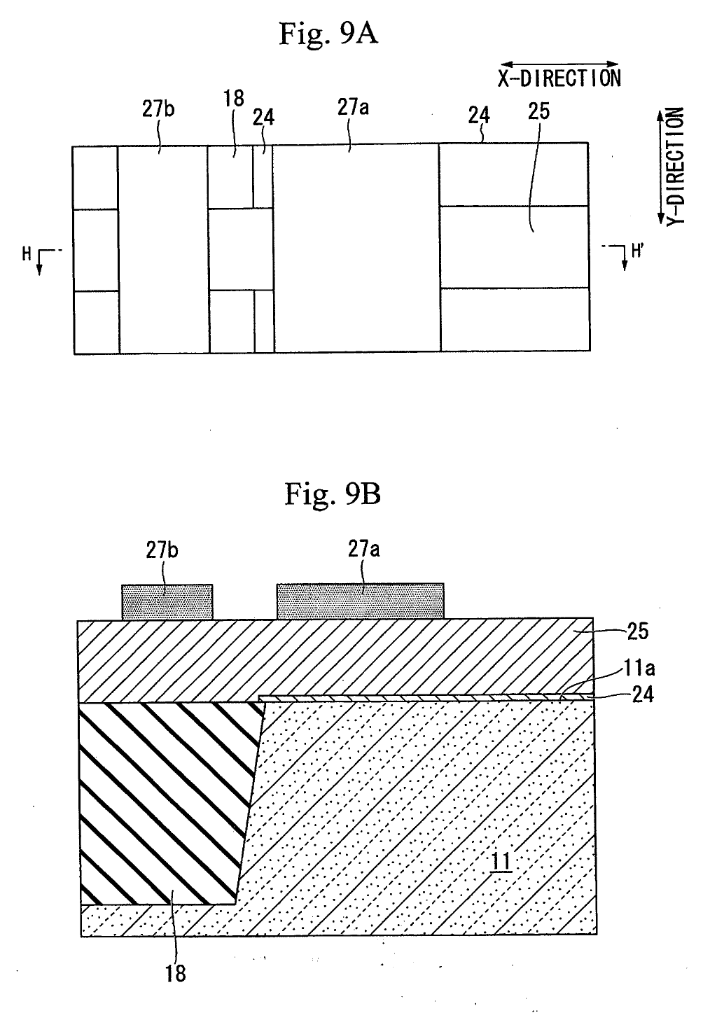

FIGS. 9A and 9B are views when the resist masks 27a and 27b are formed. FIG. 9A is a plan view. FIG. 9B is a cross-sectional view taken along the H-H′ line of FIG. 9A. The lines of these resist masks 27a and 27b are formed along the direction perpendicular to the above-mentioned X-direction, that is, the Y-direction. The above-mentioned Y-direction is also the <100> direction of the silicon wafer.

The silicon nitride film 25 is removed by a dry-etching process using these resist masks 27a and 27b so that the thermal oxide film 24 is exposed.

The resist masks 27a and 27b are removed.

The silicon oxide film 24 is removed, and then the surface 11a of the substrate 11 is exposed.

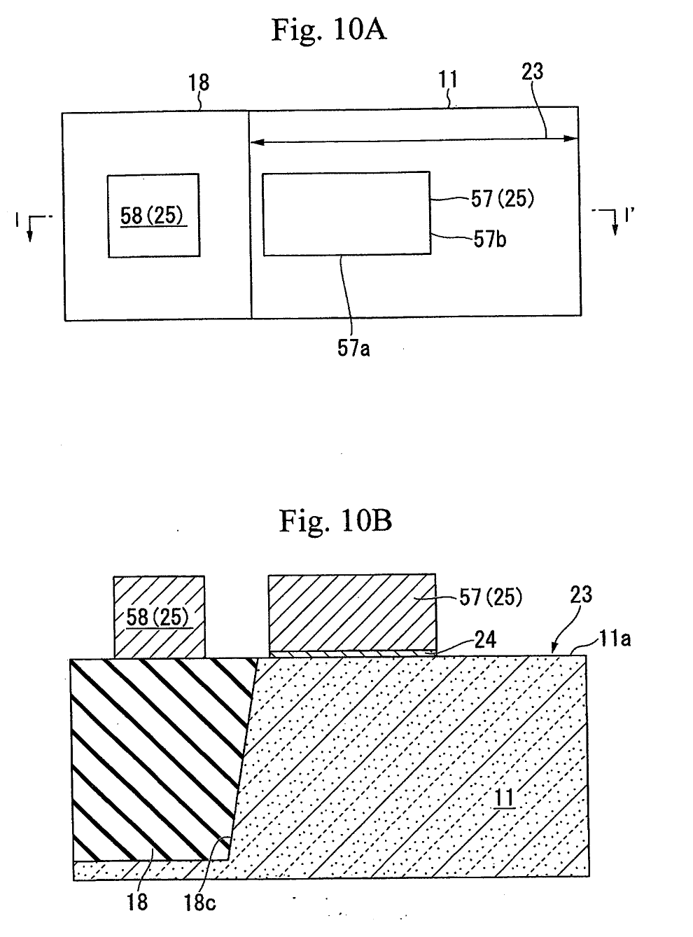

FIGS. 10A and 10B are views when the silicon oxide film 24 is removed. FIG. 10A is a plan view. FIG. 10B is a cross-sectional view taken along the I-I′ line of FIG. 10A.

As shown in FIG. 10, a protrusion forming mask 57 made of the silicon nitride film 25 which is shaped in rectangle in plan view remains in the active region 23. A dummy pillar forming mask 58 made of the silicon nitride film 25 which is square-shaped in plan view remains in the isolation region 18.

Each side of the protrusion forming mask 57 is perpendicular to the <100> direction. For example, the length of the long side 57a of the protrusion forming mask 57 is 70 nm, and the length of the short side 57b thereof is 50 mm The length of each side of the dummy pillar forming mask 58 is 50 nm.

The dummy pillar forming mask 58 is substantially square-shaped in plan view, but is not limited thereto, and it may be rectangle in plan view and may also be circular in plan view. In addition, even when it is rectangle in plan view, the direction of each side may be freely selected, and the direction of each side need not be arranged in a direction perpendicular to the <100> direction.

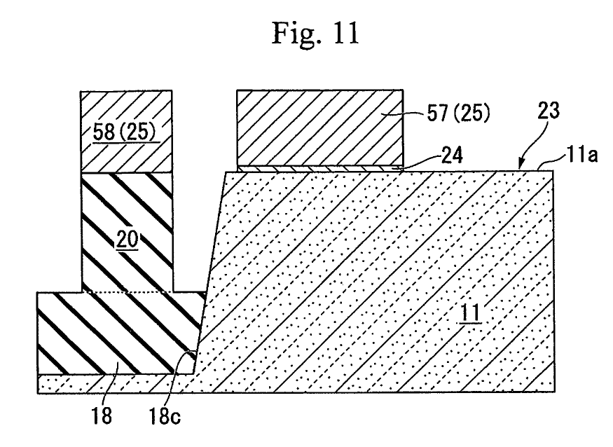

The insulating materials made of a silicon oxide film of the isolation region 18 are dry-etched using the dummy pillar forming mask 58, and then the dummy pillar 20 made of a silicon oxide film is formed, as shown in FIG. 11. The height of the dummy pillar 20 is for example 150 nm. The dummy pillar forming mask 58 remains at the top of the dummy pillar 20.

At the time of this dry etching, the silicon of the substrate 11 is not etched. For this reason, in the active region 23, the extension portion forming mask 57 made of the silicon oxide film 24 and the silicon nitride film 25 remain on the surface 11a of the substrate 11 while being stacked in this order.

The silicon of the substrate 11 of the active region 23 is dry-etched in a vertical direction from the surface 11a using the extension portion forming mask 57, and then a protrusion 47 is formed. The height of the protrusion 47 is for example 150 nm.

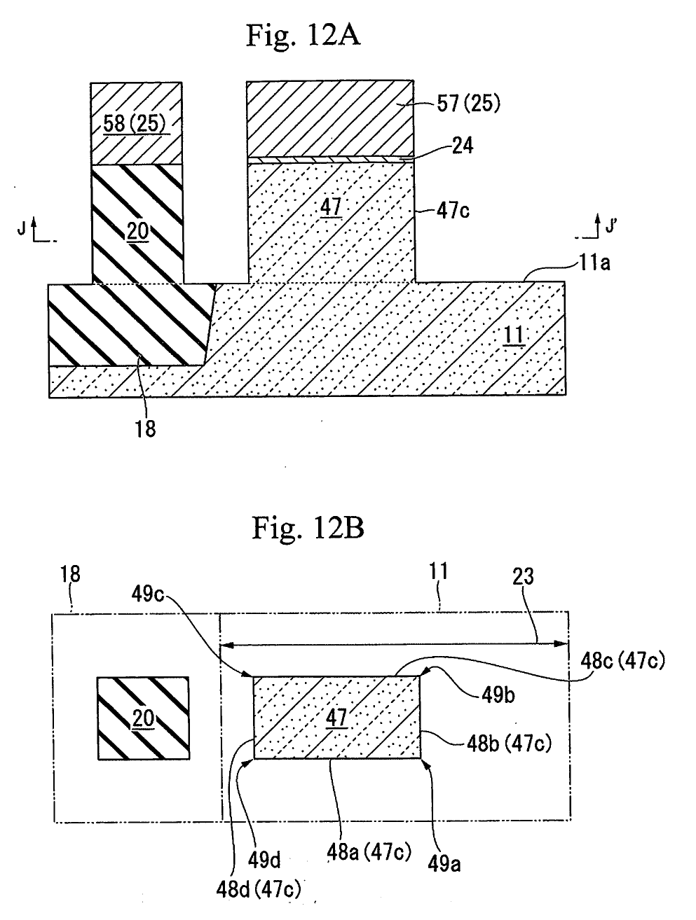

FIGS. 12A and 12B are views when the protrusion 47 is formed. FIG. 12A is a cross-sectional view. FIG. 12B is a cross-sectional view taken along the J-J′ line of FIG. 12A.

As shown in FIG. 12B, the protrusion 47 is rectangle in plan view. The side surfaces 47c of the protrusion 47 are the {100} face. The side surfaces 47c may include four side surfaces 48a, 48b, 48c, and 48d. The side surfaces 48a and 48c are the opposite sides. The side surfaces 48c and 48d are the opposite sides.

At the time of this dry etching, the silicon oxide film is not etched. For this reason, the insulating materials buried in the groove 18c, the dummy pillar 20, and the dummy pillar forming mask 58 remain in the isolation region 18 while being stacked.

The side surfaces 47c of the protrusion 47 and the surface 11a of the substrate 11 which are the exposed surfaces of silicon are thermally oxidized by a thermal oxidation method, and then a thermal oxide film 28 made of a silicon oxide film is formed.

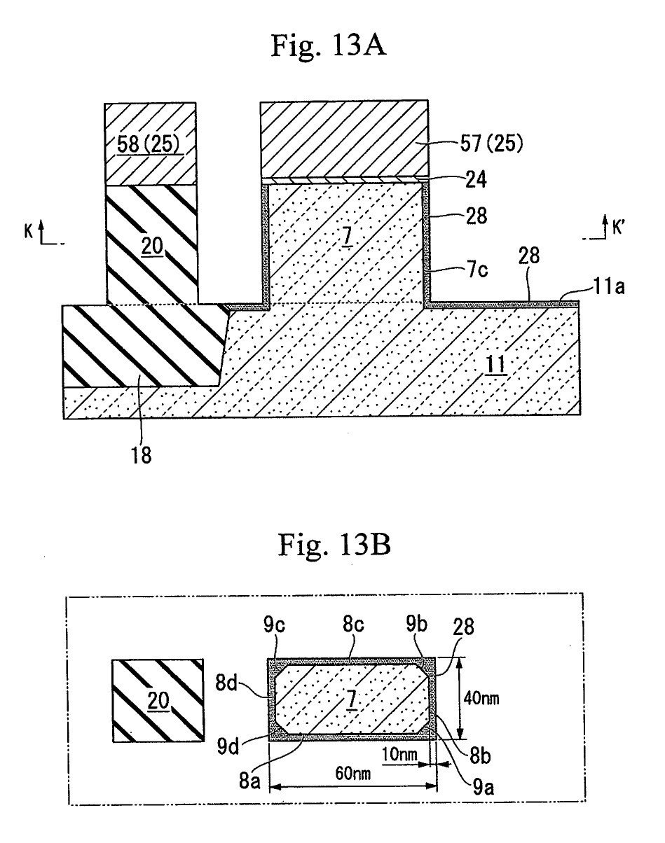

FIGS. 13A and 13B are views when the thermal oxide film 28 is formed. FIG. 13A is a cross-sectional view. FIG. 13B is a cross-sectional view taken along the K-K′ line of FIG. 13 A. Descriptions of the surface 11a of the substrate 11 are not shown in FIG. 13B.

The main surfaces 8a, 8b, 8c, and 8d of the {100} face are formed by thermal oxidation over the four side surfaces 48a, 48b, 48c, and 48d of the {100} face in the side surfaces 7c of the extending portion 7. The main surfaces 8a, 8b, 8c, and 8d have the same thickness.

The sub-surfaces 9a, 9b, 9c, and 9d of the {100} face perpendicular to the <110> direction appear at the corner portions 49a, 49b, 49c, and 49d where the {100} faces cross each other.

Even when the thermal oxidation is performed under the same conditions, the thermal oxide film of the {110} face is more easily thermally oxidized than that formed in the {100} face, and the depth of silicon which is thermally oxidized becomes deeper. Thus the thickness of the thermal oxide film which is formed in the sub-surfaces 9a, 9b, 9c, and 9d formed of the {110} face is thicker than the thickness of the thermal oxide film which is formed in the main surfaces 8a, 8b, 8c, and 8d.

As shown in FIG. 13B, by thermally oxidizing the silicon surface by a thermal oxidation method, the protrusion 47 which is shaped in rectangle in plan view becomes the extending portion 7 which is octagonal in plan view, and the side surfaces 47c of the protrusion 47 become the side surfaces 7c of the extending portion 7.

The thickness of the thermal oxide film 28 on the main surfaces 8a, 8b, 8c, and 8d is for example 10 nm on the {100} face. In that case, the width l₄ of the main surfaces 8a and 8c which are the long sides of the side surfaces 7c of the extending portion 7 is about 60 nm, and the width l₅ of the main surfaces 8b and 8d which are the short sides thereof is about 40 nm.

The width of the sub-surface 9a, 9b, 9c, 9d is for example 2 nm. In that case, for example, the thickness of the thermal oxide film 28 which is formed in the sub-surfaces 9a, 9b, 9c, and 9d is 15 nm in the <110> direction.

Arsenic implantation is performed in the surface 11a of the substrate 11 around the base of the extending portion 7, and then the lower diffusion layer 12 is formed. The above-mentioned arsenic implantation is performed by, for example, 1×10¹⁵/cm² at energy of 10 keV, and after that, heat treatment is performed for about ten seconds at 900° C.

As shown in FIG. 14, an HDP film 29 made of a silicon oxide film is formed so as to cover the lower diffusion layer 12 through the thermal oxide film 28 by an HDP (High Density Plasma) method. The thickness of the HDP film 29 is for example 30 nm. Hereby, the lower insulation film 22 in which the thermal oxide film 28 and the HDP film 29 are stacked is formed.

The thermal oxide film 28 of the side surface 7c of the extending portion 7 is removed by the wet etching method, using a buffered hydrofluoric acid. The etching depth is the depth by which the thermal oxide film 28 having a thickness of 15 nm formed on the sub-surfaces 9a, 9b, 9c, and 9d is overetched by 30%. Hereby, the thermal oxide film 28 of the side surface 7c of the extending portion 7 can be completely removed.

The above-mentioned over-etching depth can be determined by adjusting the treatment time or the treatment temperature in the buffered hydrofluoric acid. For example, if the treatment time in the buffered hydrofluoric acid is adjusted, and the side length of the face perpendicular to the <110> direction of the sub-surfaces 9a, 9b, 9c, and 9d is about 5 nm, then the width of the main surfaces 8a and 8c which are the long sides of the side surfaces 7c of the extending portion 7 is 55 nm, and the width of the main surfaces 8b and 8d which are the short sides thereof is 35 nm. Hereby, the area of the sub-surfaces 9a, 9b, 9c, and 9d formed of the (110) face can be about 11% of the area of the main surfaces 8a, 8b, 8c, and 8d of the (100) face of the side surface 7c of the extending portion 7. When the extending portion 7 is formed in a square shape of 50 nm in plan view, the area of the sub-surfaces 9a, 9b, 9c, and 9d can be about 14% of the area of the main surfaces 8a, 8b, 8c, and 8d.

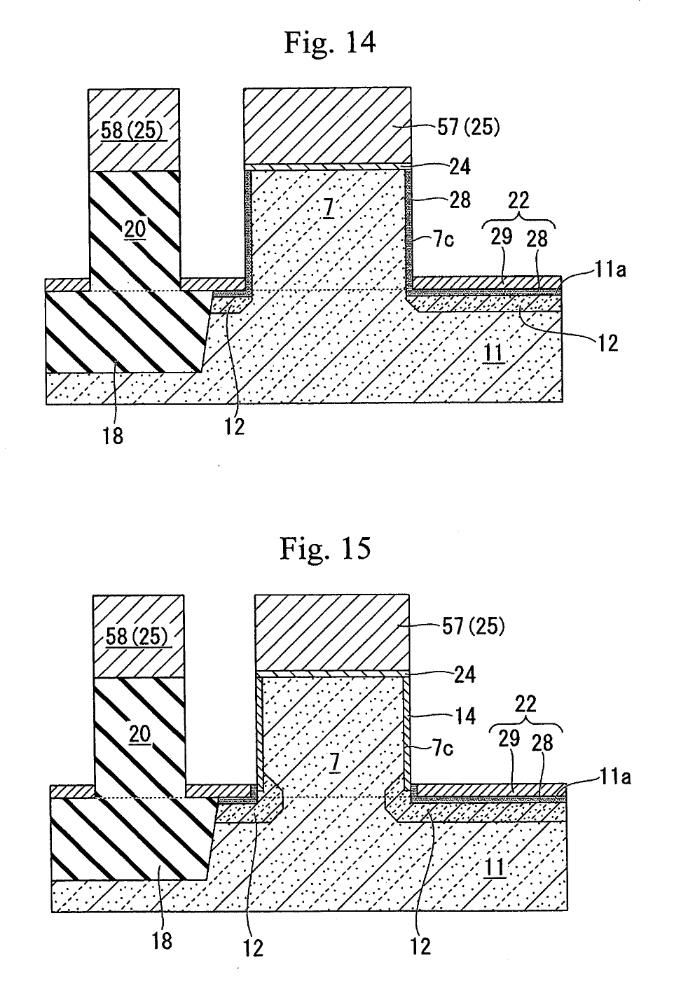

As shown in FIG. 15, the gate oxide film 14 made of a silicon oxide film is formed in the side surface 7c of the extending portion 7 by the thermal oxidation method. The thickness of the gate oxide film 14 is for example 3 nm.

The surface of the gate oxide film 14 is nitrated in the ammonia atmosphere such that the nitrogen concentration of the surface of the gate oxide film 14 is 15%.

The titanium nitride film 31 is deposited so as to cover the side surface 7c of the extending portion 7, the side surface 20c of the dummy pillar 20 and a surface 22a of the lower insulation film 22 by the CVD method. The thickness of the titanium nitride film 31 is for example 5 nm.

The tungsten film 32 is deposited so as to cover the titanium nitride film 31 by the CVD method. The thickness of the tungsten film 32 is for example 35 nm.

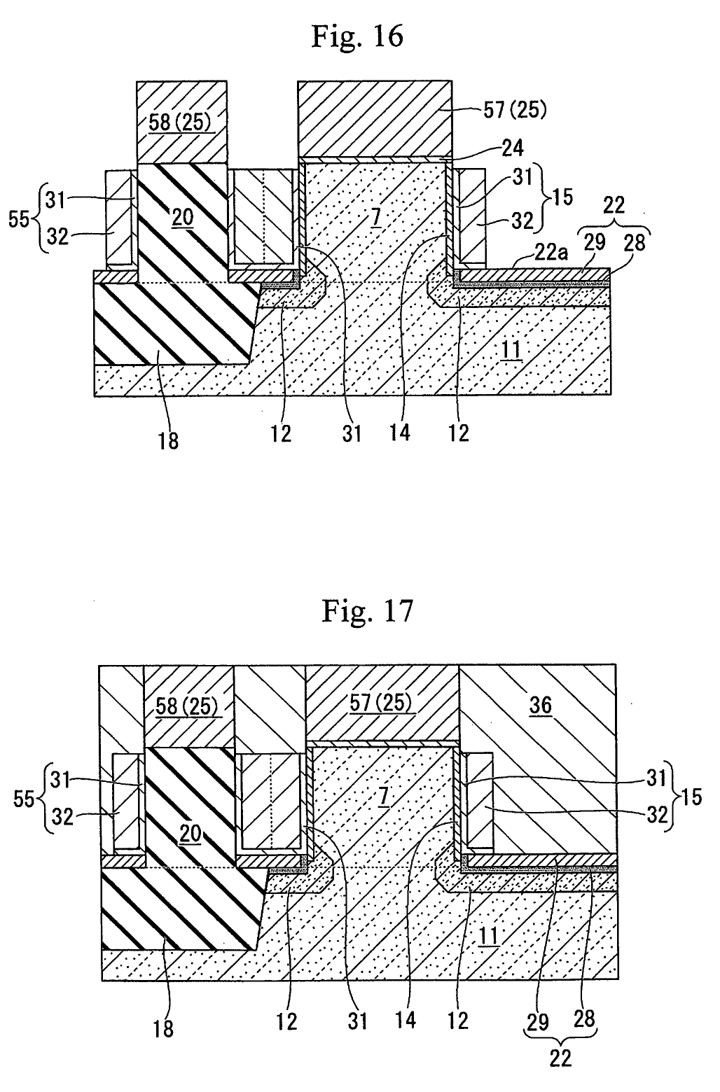

The tungsten film 32 and the titanium nitride film 31 around the extending portion 7 and the dummy pillar 20 remain. The tungsten film 32 and the titanium nitride film 31 other than those are etched back so as to be removed. Hereby, as shown in FIG. 16, it is possible to form the sidewall-shaped gate electrode 15 remaining in the side surface 7c of the extending portion 7, and a sidewall-shaped gate electrode 55 remaining in the side surface 20c of the dummy pillar 20. The gate electrode 15 and the gate electrode 55 each include the tungsten film 32 and the titanium nitride film 31, both of which are unitary formed.

An interlayer insulating film 36 made of silicon oxide is deposited over the surface 11a of the substrate 11 by the CVD method. The interlayer insulating film 36 covers the extension portion forming mask 57 and the dummy pillar forming mask 58.

As shown in FIG. 17, the interlayer insulating film 36 is planarized by a CMP (Chemical Mechanical Polishing) method so that the extension portion forming mask 57 and the dummy pillar forming mask 58 are exposed.

The extension portion forming mask 57 and the dummy pillar forming mask 58 exposed by planarizing the interlayer insulating film 36 are both removed by a thermal phosphoric acid. Hereby, a hole 60 is formed on the extending portion 7, and a hole 61 is formed on the dummy pillar 20.

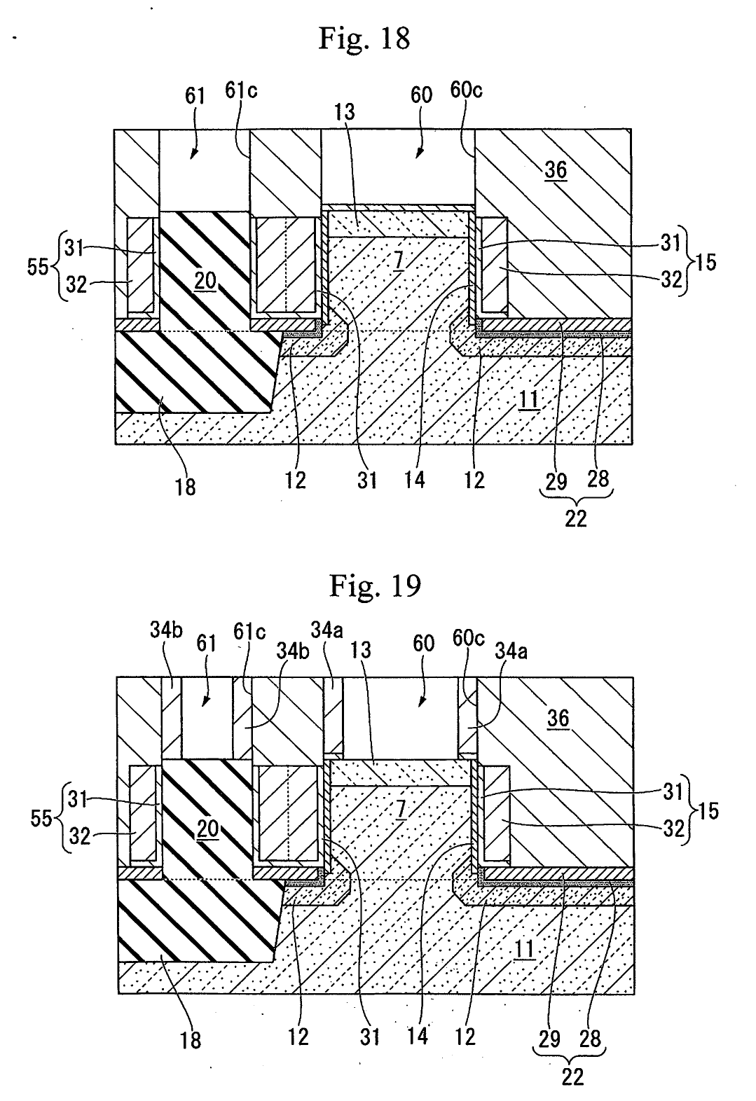

As shown in FIG. 18, arsenic is implanted at the top of the extending portion 7, and the upper diffusion layer 13 is formed. The above-mentioned arsenic implantation is performed by, for example, 1×10¹³/cm² at 10 keV.

The sidewalls 34a and 34b which are both made of silicon nitride are formed in a sidewall 60c of the hole 60 and a sidewall 61c of a hole 61, respectively.

As shown in FIG. 19, the silicon oxide film 24 at the top of the extending portion 7 is removed by etching, and the top of the extending portion 7 is exposed.

Selective epitaxial growth of silicon is performed on silicon at the top of the extending portion 7, and the plug 35 made of a silicon region is formed. The thickness of the plug 35 is for example 50 nm.

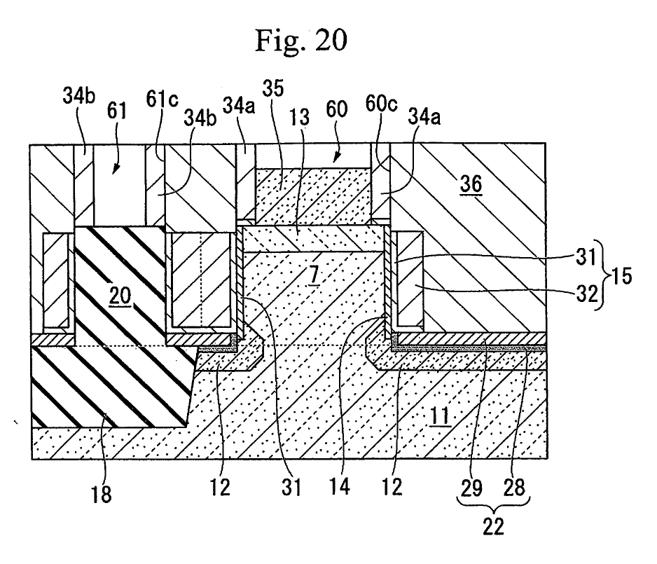

As shown in FIG. 20, arsenic is implanted in the plug 35. The above-mentioned arsenic implantation is performed by 3×10¹⁵/cm² at 30 keV. After that, heat treatment for ten seconds at 900° C. is performed. The plug 35 can be used as a portion formed by drawing out the upper diffusion layer 13.

An interlayer insulating film 37 made of silicon oxide is deposited so as to fill in the hole 60 and a hole 61, and to further cover the interlayer insulating film 36. Hereby, the interlayer insulating film 17 in which the interlayer insulating films 36 and 37 are stacked is formed.

After a resist is applied on the interlayer insulating film 36 and is dried, a mask where a hole having a predetermined size is opened in a predetermined position is formed using a predetermined photolithography method.

The interlayer insulating film 17 is etched through the above-mentioned mask, and the first hole (hereinafter, contact hole) 19c, the second hole (hereinafter, contact hole) 21c and the third hole (hereinafter, contact hole) 16c are provided.

The first contact hole 19c is a hole that exposes the plug 35 made of a silicon region, penetrating through the interlayer insulating film 17. The second contact hole 21c is a hole that exposes a portion of the gate electrode 55. The third contact hole 16c is a hole that exposes the surface 11a of the substrate 11 in which the lower diffusion layer 12 is formed.

After the above-mentioned mask is removed, a titanium film having a thickness of 5 nm, a titanium nitride film having a thickness of 10 nm, and a tungsten film having a thickness of 50 nm are stacked in this order by the CVD method so as to fill in the first contact hole 19c, the second contact hole 21c and the third contact hole 16c, respectively.

The stack of the tungsten film, the titanium nitride film and the titanium film is planarized by the CMP method, and the first plug electrode 19, the second plug electrode 21 and the third plug electrode 16 are formed. As a result, the semiconductor device 102 including the pillar MOS transistor 52 as shown in FIG. 4 is manufactured.

After the tungsten film having a thickness of 50 nm is, for example, formed on the interlayer insulating film 17, an interconnect obtained by processing this may be formed.

The semiconductor device 102 includes the substrate 11, the extending portion 7 which extends in a vertical direction from the surface 11a of the substrate 11, the upper diffusion layer 13 at the top of the extending portion 7, the lower diffusion layer 12 around the base of the extending portion 7, the gate insulating film 14 covering the side surfaces 7c of the extending portion 7, and the gate electrode 15 covering the gate insulating film 14. The semiconductor device 102 includes the pillar MOS transistor 52 of which the channel 77 is formed in the above-mentioned vertical direction. In the semiconductor device, the extending portion 7 is octagonal in plan view. The side surfaces 7c of the extending portion 7 may be four main surfaces 8a, 8b, 8c, and 8d of the {100} face, and the four sub-surfaces 9a, 9b, 9c, and 9d of the {110} face. The four sub-surfaces 9a, 9b, 9c, and 9d have smaller areas than the main surfaces 8a,8b, 8c, and 8d, thereby reducing the surface roughness of the side surfaces 7c of the extending portion 7. In the semiconductor device, even when the gate oxide film 14 is formed so as to cover the side surfaces 7c, the effective channel length is not increased, and thus it is possible to suppress lowering of the current driving capability of the pillar MOS transistor 52. In addition, it is possible to prevent an increase in the leakage of current of the gate insulating film 14, and to prevent lowering of the ON current. As a result, it is possible to provide the pillar MOS transistor having high current driving capability in a low leakage of current.

The semiconductor device 102 in accordance with an embodiment of the invention is configured such that the area in total of the four sub-surfaces 9a, 9b, 9c, and 9d is within the range of 10% to 30% of the area in total of the four main surfaces 8a, 8b, 8c, and 8d, thereby reducing the surface roughness of the side surfaces 7c of the extending portion 7. In the semiconductor device, even when the gate oxide film 14 is formed so as to cover the side surfaces 7c, the effective channel length is not increased, and thus it is possible to suppress the lowering of the current driving capability of the pillar MOS transistor 52.

The semiconductor device 102 in accordance with an embodiment of the invention is configured such that the gate insulating film 14 on the sub-surfaces 9a, 9b, 9c, and 9d is thicker than the gate insulating film 14 on the main surfaces 8a, 8b, 8c, and 8d. When the gate oxide film 14 is formed so as to cover the side surfaces 7c, it is possible to suppress the influence of the surface roughness of the sub-surfaces 9a, 9b, 9c, and 9d of the side surface 7c of the extending portion 7. This reduces the field concentration in the sub-surfaces 9a, 9b, 9c, and 9d. This improves reliability of the current driving capability of the pillar MOS transistor 52.

The method of manufacturing the semiconductor device 102 includes a process of forming the protrusion 47, which is shaped in rectangle in plan view, having four side surfaces 48a, 48b, 48c, and 48d of the {100} face, by etching the surface 11a of the substrate 11 in a vertical direction from the surface 11a, and a process of forming the extending portion 7, octagonal in plan view, of which the side surfaces 7c may be four main surfaces 8a, 8b, 8c, and 8d of the {100} face, and the four sub-surfaces 9a, 9b, 9c, and 9d of the {110} face, which have smaller areas than the main surfaces 8a, 8b, 8c, and 8d, by forming the thermal oxide film 28 in the side surface 47c of the protrusion 47, and then removing the thermal oxide film 28. Therefore it is possible to suppress the surface roughness of the side surfaces 7c of the extending portion 7. Hereby, even when the gate oxide film 14 is formed so as to cover the side surfaces 7c, the effective channel length is not increased, and thus it is possible to suppress the lowering of the current driving capability of the pillar MOS transistor 52.

The method of manufacturing the semiconductor device 102 is configured such that removal of the thermal oxide film 28 is performed by the wet etching, whereby it is possible to suppress the surface roughness of the side surface 7c of the extending portion 7.

The method of manufacturing the semiconductor device 102 includes a process of forming the gate insulating film 14 so as to cover the side surfaces 7c of the extending portion 7, after the protrusion 47 is formed to be the extending portion 7 which is octagonal in plan view. The method also includes a process of forming the gate electrode 15 so as to cover the gate insulating film 14. The surface roughness of the side surfaces 7c of the extending portion 7 is suppressed. In the method, even when the gate oxide film is formed so as to cover the side surfaces 7c, the effective channel length is not increased, and thus it is possible to suppress the lowering of the current driving capability of the pillar MOS transistor 52.

The method of manufacturing the semiconductor device 102 includes a process of forming the lower diffusion layer 12 by implanting ions in the base of the protrusion 47, after the thermal oxide film 28 is formed. The method also includes a process of forming the upper diffusion layer 13 by implanting ions at the top of the extending portion 7, after the gate electrode 15 is formed. The surface roughness of the side surfaces 7c of the extending portion 7 is suppressed. In the method, even when the gate oxide film is formed so as to cover the side surfaces 7c, the effective channel length is not increased, and thus it is possible to suppress the lowering of the current driving capability of the pillar MOS transistor 52.

### Examples

Examples will be described in detail. However, the invention is not limited to these examples.

### Example 1

A groove 18c having a depth of 300 nm was formed in a predetermined region of the p-type silicon substrate 11, using the etching method. Insulating materials such as a silicon oxide film were filled in the above-mentioned groove 18c, and an isolation region 18 was formed. Ions were implanted up to a depth of 500 nm from the surface 11a of the substrate 11 so that the boron concentration became substantially 2×10¹⁷/cm³, and an active region 23 was formed.

A silicon oxide film 24 having a thickness of 5 nm was formed in the substrate surface 11a of the active region 23 by a thermal oxidation method. A silicon nitride film 25 having a thickness of 100 nm was formed by the CVD method so as to cover the silicon oxide film 24 and the isolation region 18.

A resist was applied so as to cover the silicon nitride film 25, and then, a line-shaped resist mask 26 extending in the X-direction which is <100> direction was formed by a lithography method. The silicon nitride film was dry-etched using the above-mentioned resist mask. The resist mask 26 was removed.

Two line-shaped resist masks 27a and 27b having different widths were formed in the Y-direction which is perpendicular to the X-direction and is <100> direction by the lithography method. The silicon nitride film 25 was processed by etching, using these resist masks 27a and 27b. The silicon oxide film 24 of the active region was removed, and the silicon surface of the substrate 11 was exposed.

The resist masks 27a and 27b were removed. Hereby, a protrusion 57 was formed in the active region. The protrusion 57 may perform as a mask of silicon nitride. The protrusion 57 is shaped in rectangle in plan view. The protrusion 57 has four sides perpendicular to the <100> direction, of which the long side 57a is 70 nm and the short side 57b is 50 nm. Simultaneously, a dummy pillar 58 was formed in the isolation region 18. The dummy pillar 58 performs a mask made of silicon nitride which is square-shaped in plan view, of which one side is 50 nm.

The insulating materials made of silicon oxide of the isolation region were dry-etched using the dummy pillar forming mask. Hereby, a dummy pillar 58 is formed which is made of silicon oxide. The dummy pillar 58 of a height of 150 nm was formed in the isolation region.

Silicon of the active region was dry-etched using the protrusion forming mask 57, and a protrusion 47 having a height of 150 nm was formed.

The exposed surface of silicon was oxidized by a thermal oxidation method. Hereby, a silicon oxide film 28 having a thickness of 10 nm was formed in the side surface of the protrusion 47 and the surface of the substrate 11.

A silicon oxide film (thermal oxide film) 29 having a thickness of 10 nm was formed on the main surface of the {110} face of the side surface of the protrusion 47 by the thermal oxidation method.

As a result, the width of the main surface corresponding to the long side of the side surfaces of the protrusion 47 is about 60 nm, and the width of the main surface corresponding to the short side thereof is about 40 nm. At the corner portions in which the {110} faces cross each other, the surface substantially perpendicular to the <110> direction of the side, that is, the sub-surface, have a width of 2 nm. As a result, the protrusion 47 which is shaped in rectangle in plan view was formed to be an extension portion 7 which is octagonal in plan view. The thickness of the silicon oxide film formed on this sub-surface was 15 nm in the <110> direction.

Arsenic was implanted in a region of the surface 11a of the substrate 11 around the base of the extension portion 7, and a lower diffusion layer was formed. The above-mentioned arsenic implantation was performed by, for example, 1×10¹⁵/cm² at energy of 10 keV. After that, heat treatment for about ten seconds at 900° C. was performed.

The silicon oxide film having a thickness of 30 nm was formed by an HDP method so as to cover the upper surface of the lower diffusion layer through the silicon oxide film.

The silicon oxide film of the side surface of the extension portion 7 was removed by a buffered hydrofluoric acid. In this case, the silicon oxide film having a thickness of 16 nm formed on the sub-surface was over-etched to a degree of 30% so that the silicon oxide film on the sub-surface was also completely removed.

The side length of the surface perpendicular to the <110> direction at the corner portions in which {100} faces cross each other was about 5 nm so that the treating time by the buffered hydrofluoric acid was adjusted and the side length did not become excessively large due to appearance of the {110} face having a slow etching rate of silicon. Hereby, when a gate oxide film was formed, the side length of the surface perpendicular to the <100> direction was configured such that the long side was 55 nm and the short side was 35 nm. The side length of the surface perpendicular to the <110> direction was about 5 nm. The area of the sub-surface of the {110} face was about 11% of the area of the main surface of the {100} face of the side surface 7c of the extending portion 7.

A gate oxide film 31 having a thickness of 3 nm was formed in the side surface 7c of the extending portion 7 by a thermal oxidation method.

The surface of the gate oxide film 31 was nitrified so that the nitrogen concentration of the surface of the gate oxide film was 15% in an ammonia atmosphere.

A titanium nitride film having a thickness of about 5 nm was deposited by the CVD method so as to cover the side surface 7c of the extending portion 7, the side surface of the dummy pillar 20 and the surfaces of the silicon oxide film 31. A tungsten film 32 having a thickness of about 35 nm was deposited by the CVD method so as to cover the titanium nitride film.

The tungsten film 32 and the titanium nitride film 31 were etched back. Hereby, a sidewall gate electrode 15 made of the tungsten film 32 and the titanium nitride film 31 was formed in the side surface 7c of the extending portion 7, and a sidewall gate electrode 55 made of the tungsten film 31 and the titanium nitride film 32 was formed in the side surface of the dummy pillar 20.

An interlayer insulating film 36 made of a silicon oxide film was deposited in the surface side of the substrate 11 by the CVD method so as to cover the protrusion forming mask 57 and the dummy pillar forming mask 58. The interlayer insulating film 36 was planarized by the CMP, and the protrusion forming mask 57 and the dummy pillar forming mask 58 were exposed.

The protrusion forming mask 57 and the dummy pillar forming mask 58 exposed by the above-mentioned planarization were respectively removed by a thermal phosphoric acid. Hereby, holes 60 and 61 were respectively formed at the top of the extending portion 7 and the top of the dummy pillar 20. Arsenic was implanted only at the top of the protrusion by 1×10¹³/cm² at 10 keV, and an upper diffusion layer 13 was formed.

The sidewalls 34a and 34b of a silicon nitride film were formed in the sidewalls 60c and 61c of the above-mentioned two holes 60 and 61. The silicon oxide film at the top of the protrusion was removed by etching, and the top of the protrusion was exposed.

Selective epitaxial growth was performed on silicon at the top of the extending portion 7, and a plug 35 made of a silicon region having a thickness of 50 nm was formed. Arsenic was implanted in the plug by 3×10¹⁵/cm² at 30 keV. After that, heat treatment for ten seconds at 900° C. was performed.

An interlayer insulating film made of a silicon oxide film was formed so as to fill in the hole and cover the interlayer insulating film. After a contact hole in which a portion of the silicon region is exposed was provided so as to penetrating through the interlayer insulating film and the interlayer insulating film, a titanium film having a thickness of 5 nm, a titanium nitride film having a thickness of 10 nm, and a tungsten film having a thickness of 50 nm were stacked in the contact hole by the CVD method in this order, and then the stack of the tungsten film, the titanium nitride film and the titanium film was planarized by the CMP method, and the first plug electrode was formed.

In addition, after a contact hole in which a portion of a gate electrode is exposed was provided in the interlayer insulating film, metallic materials were filled within the contact hole similarly to the first plug electrode, and then a second plug electrode was formed. After one surface of the substrate, the contact hole in which the lower diffusion layer is exposed was provided in the interlayer insulating film, metallic materials were filled within the contact hole similarly to the first plug electrode, and then a third plug electrode was formed.

After a tungsten film having a thickness of 50 nm was formed on an interlayer insulating film, a semiconductor device including a pillar MOS transistor (hereinafter, semiconductor device of Example 1) was manufactured, using an interconnect by processing this.

### Examples 2 to 5

Semiconductor devices of Examples 2 to 5 were manufactured similarly to Example 1 excepted that the ratio of the sub-surface area to the main surface area (hereinafter, area ratio) was changed to 0.8 (Example 2), 1.3 (Example 3), 2.1 (Example 4), and 2.7 (Example 5). The sub-surface area is an area of the sub-surface formed of the (110) face, and the main surface area is an area of the main surface formed of the (100) face of the side surface of the pillar (hereinafter, the same).

### Characteristic of Drain Current to Gate Voltage:

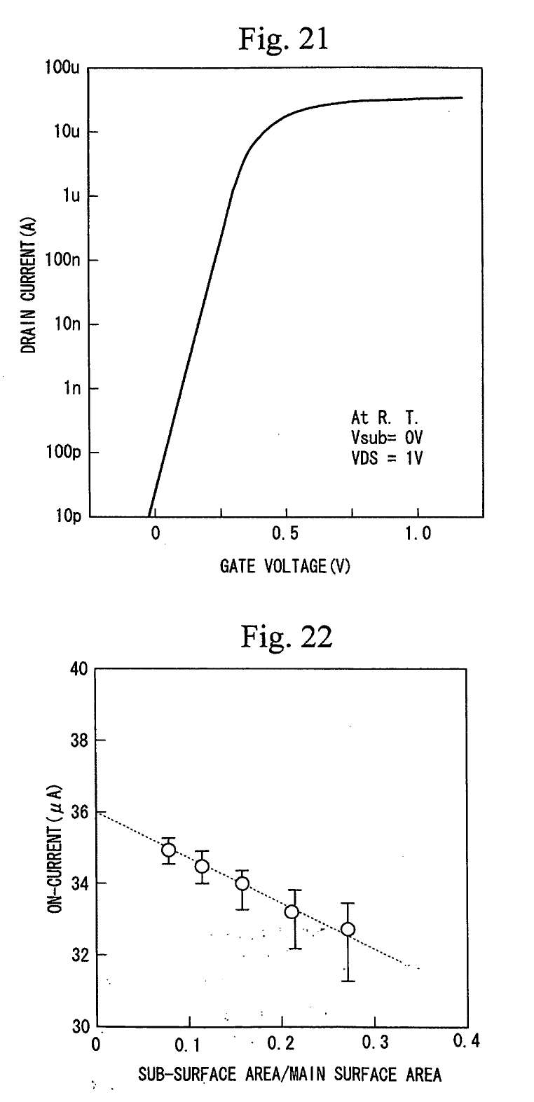

FIG. 21 is a graph illustrating a characteristic of a drain current to a gate voltage of the semiconductor device of Example 1. The measurement conditions of the characteristic of current to voltage are room temperature, Vsub=0V, and VDS=1V. Vsub is a substrate potential, and VDS is a source and drain potential.

As shown in FIG. 21, in the semiconductor device of Example 1, the drain current is rapidly increased with an increase in the gate voltage in a the state where the gate voltage is within the range from about 0V up to about 0.4V, while the drain current is gradually increased in response to the channel resistance in the state where the gate voltage is within the range from about 0.4V up to about 1.0V.

FIG. 22 is a graph illustrating a relationship between the current driving capability (hereinafter, ON current) and the area ratio of the semiconductor device of Examples 1 to 5, and is a graph illustrating the area ratio dependence of the ON current.

As shown in FIG. 22, the ON current was decreased when the above-mentioned area ratio became larger. In addition, variation of the ON current became larger when the area ratio became larger.

An influence of the surface roughness of the sub-surface has been considered as a cause of variation of the ON current. In other words, it has been considered that when the area of the sub-surface becomes larger due to the large surface roughness of the sub-surface, lowering of the current driving capability is brought about, the ON current is reduced, and the current driving capability is varied, which results in the variation of the ON current.

The point where the area of the sub-surface becomes substantially zero, that is, the ON current in a case where the influence of the surface roughness of the sub-surface is negligible was 36 μA if estimated from the graph.

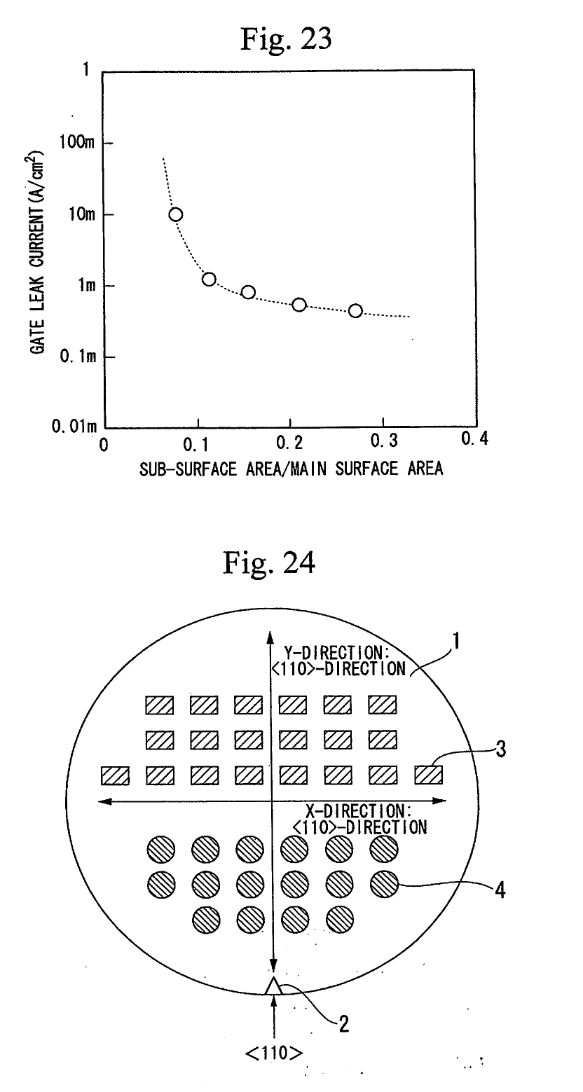

FIG. 23 is a graph illustrating a relationship between a gate leakage of current and an area ratio of the semiconductor device of Examples 1 to 5, and is a graph illustrating the area ratio dependence of the gate leakage of current.

As shown in FIG. 23, in the range where the above-mentioned area ratio is equal to or less than 0.1 (corresponding to 10% of the area of the main surface with respect to the area of the sub-surface), the lowering rate of the ON current became larger, and the gate leakage of current was rapidly lowered along with an increase in the above-mentioned area ratio. On the other hand, in the range where the area ratio is from 0.1 (corresponding to 10% of the area of the main surface with respect to the area of the sub-surface) to 0.3 (corresponding to 30% of the area of the main surface with respect to the area of the sub-surface), the lowering rate of the ON current became smaller, and the gate leakage of current was not substantially lowered.

The above-described embodiments and examples provide the semiconductor device and a method of manufacturing the semiconductor device. Particularly the above-described embodiments and examples provides a semiconductor device, including a pillar MOS transistor where a channel is formed in a direction perpendicular to the substrate surface, suppressing shape roughness of the pillar side, suppressing deterioration of transistor characteristics, and raising reliability of a gate insulating film. The method is to manufacture these semiconductor devices.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least 5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a semiconductor substrate; and
an extending semiconductor portion that extends vertically from the semiconductor substrate, the extending semiconductor portion having a side surface which comprises four main surfaces of {100} face and four sub-surfaces of {110} face, the four sub-surfaces being smaller in area than the four main surfaces.

2. The semiconductor device according to claim 1, wherein a total area of the four sub-surfaces is in the range of 10% to 30% of a total area of the main surfaces.

3. The semiconductor device according to claim 1, wherein each of the four sub-surfaces is between two adjacent main surfaces of the four main surfaces, and each of the four main surfaces is between two adjacent sub-surfaces of the four sub-surfaces.

4. The semiconductor device according to claim 1, further comprising:
a gate insulating film that comprises four main portions covering the four main surfaces of {100} face, and four sub-portions covering the four sub-surfaces of {110} face.

5. The semiconductor device according to claim 4, wherein the four main portions are thinner than the four sub-portions.

6. The semiconductor device according to claim 1, wherein the extending semiconductor portion has a shape defined by eighth sides and eight angles in plan view.

7. The semiconductor device according to claim 6, wherein first two of the four main surfaces are positioned in first opposing sides and second two of the four main surfaces are positioned in second opposing sides, and the first two of the four main surfaces are greater in width than the second two of the four main surfaces.

8. The semiconductor device according to claim 7, wherein the second two of the four main surfaces are greater in width than the four sub-surfaces.

9. The semiconductor device according to claim 1, further comprising:
a lower diffusion region in the semiconductor substrate, the lower diffusion region being disposed around a base of the extending semiconductor portion;
an upper diffusion region on an upper surface of the extending semiconductor portion;
a first gate insulating film covering the side surface of the extending semiconductor portion; and
a first gate electrode on the first gate insulating film.

10. The semiconductor device according to claim 9, wherein the first gate insulating film includes thicker portions covering the four main surfaces and thinner portions covering the four sub-surfaces, the thicker portions are thicker than the thinner portions.

11. The semiconductor device according to claim 6, wherein a channel length is vertical to a surface of the semiconductor substrate.

12. The semiconductor device according to claim 9, further comprising:
an insulating pillar vertically extending from a surface of an isolation region of the semiconductor substrate; and
a second gate electrode covering a side surface of the insulating pillar, the second gate electrode being in contact with the first gate electrode.

13. The semiconductor device according to claim 12, further comprising:
an interlayer insulating film that covers the extending semiconductor portion, the insulating pillar, and the first and second gate electrodes;
a first plug in the interlayer insulating film, the first plug being connected to the upper diffusion region;
a second plug in the interlayer insulating film, the second plug being connected to a distal portion of the second gate electrode, the distal portion being distal from the first gate electrode; and
a third plug in the interlayer insulating film, the third plug being connected to the lower diffusion region.

14. The semiconductor device according to claim 1, wherein the extending semiconductor portion is made of the same semiconductor of the semiconductor substrate.

15. A semiconductor device comprising:
a semiconductor substrate;
an extending semiconductor portion that extends vertically from the semiconductor substrate, the extending semiconductor portion having a side surface which comprises four main surfaces of {100} face and four sub-surfaces of {110} face, a total area of the four sub-surfaces being smaller than a total area of the four main surfaces;
a gate insulating film that comprises four main portions covering the four main surfaces of {100} face, and four sub-portions covering the four sub-surfaces of {110} face, the four main portions being thinner than the four sub-portions; and
a first gate electrode on the first gate insulating film.

16. The semiconductor device according to claim 15, wherein the total area of the four sub-surfaces is in the range of 10% to 30% of the total area of the main surfaces.

17. The semiconductor device according to claim 15, further comprising:
a lower diffusion region in the semiconductor substrate, the lower diffusion region being disposed around a base of the extending semiconductor portion; and
an upper diffusion region on an upper surface of the extending semiconductor portion.

18. The semiconductor device according to claim 17, further comprising:
an insulating pillar vertically extending from a surface of an isolation region of the semiconductor substrate;
a second gate electrode covering a side surface of the insulating pillar, the second gate electrode being in contact with the first gate electrode;
an interlayer insulating film that covers the extending semiconductor portion, the insulating pillar, and the first and second gate electrodes;
a first plug in the interlayer insulating film, the first plug being connected to the upper diffusion region;
a second plug in the interlayer insulating film, the second plug being connected to a distal portion of the second gate electrode, the distal portion being distal from the first gate electrode; and
a third plug in the interlayer insulating film, the third plug being connected to the lower diffusion region.

19. A semiconductor device comprising:
a semiconductor substrate;
an extending semiconductor portion that extends vertically from the semiconductor substrate, the extending semiconductor portion having a side surface which comprises four main surfaces of {100} face and four sub-surfaces of {110} face, the four sub-surfaces being smaller in area than the four main surfaces;
a gate insulating film that comprises four main portions covering the four main surfaces of {100} face, and four sub-portions covering the four sub-surfaces of {110} face, the four main portions being thinner than the four sub-portions;
a first gate electrode on the first gate insulating film;
a lower diffusion region in the semiconductor substrate, the lower diffusion region being disposed around a base of the extending semiconductor portion;
an upper diffusion region on an upper surface of the extending semiconductor portion;
an insulating pillar vertically extending from a surface of an isolation region of the semiconductor substrate; and
a second gate electrode covering a side surface of the insulating pillar, the second gate electrode being in contact with the first gate electrode.

20. The semiconductor device according to claim 19, wherein the total area of the four sub-surfaces is in the range of 10% to 30% of the total area of the main surfaces.
